(19) United States
(12) Patent Application Publication
(10) Pub. No.: US 2024/0321360 A1
(43) Pub. Date: Sep. 26, 2024

(54) SEMICONDUCTOR MEMORY DEVICE AND MEMORY SYSTEM

(71) Applicant: Kioxia Corporation, Tokyo (JP)

(72) Inventors: Yasuhiro HIRASHIMA, Kawasaki Kanagawa (JP); Masaru KOYANAGI, Tokyo (JP)

(73) Assignee: Kioxia Corporation, Tokyo (JP)

(21) Appl. No.: 18/732,188

(22) Filed: Jun. 3, 2024

Related U.S. Application Data
(63) Continuation of application No. PCT/JP2022/001095, filed on Jan. 14, 2022.

(51) Int. Cl. G11C 16/10; G11C 16/04; G11C 16/26

(52) U.S. Cl. CPC G11C 16/10; G11C 16/0483; G11C 16/26

(57) ABSTRACT

According to one embodiment, a semiconductor memory device includes a nonvolatile memory cell, a detection circuit which detects a first voltage and selects one of a first mode and a second mode based on the first voltage, and a transmitting unit which outputs a first signal corresponding to the one of the first mode and the second mode. The detection circuit selects the first mode when the first voltage is equal to or greater than a determination value, and selects the second mode when the first voltage is less than the determination value. The transmitting unit outputs the first signal of a first amplitude in the first mode, and outputs the first signal of a second amplitude that is smaller than the first amplitude in the second mode.

### CROSS-REFERENCE TO RELATED APPLICATIONS

This application is a Continuation Application of PCT Application No. PCT/JP2022/001095, filed Jan. 14, 2022, the entire contents of all of which are incorporated herein by reference.

### FIELD

Embodiments of the present invention relate to a semiconductor memory device and a memory system.

### BACKGROUND

A memory system to which a NAND flash memory is applied is known as a semiconductor memory device.

### BRIEF DESCRIPTION OF THE DRAWINGS

FIG. 1 is a block diagram showing the overall configuration of a data processing apparatus including a memory system according to a first embodiment.

FIG. 2 is a block diagram showing a basic configuration of a semiconductor memory device according to the first embodiment.

FIG. 3 is a circuit diagram of a memory cell array provided in the semiconductor memory device according to the first embodiment.

FIG. 4 is a block diagram of a memory interface circuit provided in a memory controller according to the first embodiment.

FIG. 5 is a block diagram of an input/output circuit provided in the semiconductor memory device according to the first embodiment.

FIG. 6 is a circuit diagram of a detection circuit provided in the memory controller according to the first embodiment.

FIG. 7 is a circuit diagram of a detection circuit provided in the semiconductor memory device according to the first embodiment.

FIG. 8 is a circuit diagram of a receiving unit and a termination circuit in a transmit/receive circuit 104 provided in the memory controller according to the first embodiment.

FIG. 9 is a circuit diagram of a receiving unit and a termination circuit in a transmit/receive circuit 105 provided in the semiconductor memory device according to the first embodiment.

FIG. 10 is a circuit diagram of a receiving unit and a termination circuit in a transmit/receive circuit 224 of the semiconductor memory device according to the first embodiment.

FIG. 11 is a circuit diagram of a receiving unit and a termination circuit in a transmit/receive circuit 225 provided in the semiconductor memory device according to the first embodiment.

FIG. 12 is a circuit diagram of a transmitting unit provided in the memory controller according to the first embodiment.

FIG. 13 is a circuit diagram of a transmitting unit provided in the semiconductor memory device according to the first embodiment.

FIG. 14 is a conceptual diagram of transmission of signal DQ from the transmitting unit of the semiconductor memory device to a receiving unit of the memory controller according to the first embodiment.

FIG. 15 is a diagram showing an example of signal waveforms of signals input to the receiving unit provided in the memory controller according to the first embodiment in an LTT mode and a PI LTT mode.

FIG. 16 is a block diagram showing the overall configuration of a data processing apparatus including a memory system according to a second embodiment.

### DETAILED DESCRIPTION

In general, according to one embodiment, a semiconductor memory device includes a nonvolatile memory cell, a detection circuit which detects a first voltage and selects one of a first mode and a second mode based on the first voltage, and a transmitting unit which outputs a first signal corresponding to the one of the first mode and the second mode. The detection circuit selects the first mode when the first voltage is equal to or greater than a determination value, and selects the second mode when the first voltage is less than the determination value. The transmitting unit outputs the first signal of a first amplitude in the first mode, and outputs the first signal of a second amplitude that is smaller than the first amplitude in the second mode.

Embodiments will be described below with reference to the drawings. Each of the embodiments exemplifies a device and a method for embodying the technical concept of the invention. The drawings are schematic or conceptual, and the dimension, ratio and the like in each of the drawings are not necessarily the same as the actual ones. The descriptions of one embodiment are all applied as those of another embodiment unless they are excluded explicitly or obviously. The technical concept of the present invention is not specified by the shape, configuration, placement and the like of the components.

In the following descriptions, the components having substantially the same function and configuration are denoted by the same symbol. The number subsequent to a letter or letters in a reference symbol is used to distinguish components referred to by reference symbols including the same letter or letters and having the same configuration. If the components denoted by reference symbols including the same letter or letters need not be distinguished from each other, the components include only the letter or letters.

### 1. First Embodiment

### 1.1 Configuration

### 1.1.1 Configuration of Data Processing Device

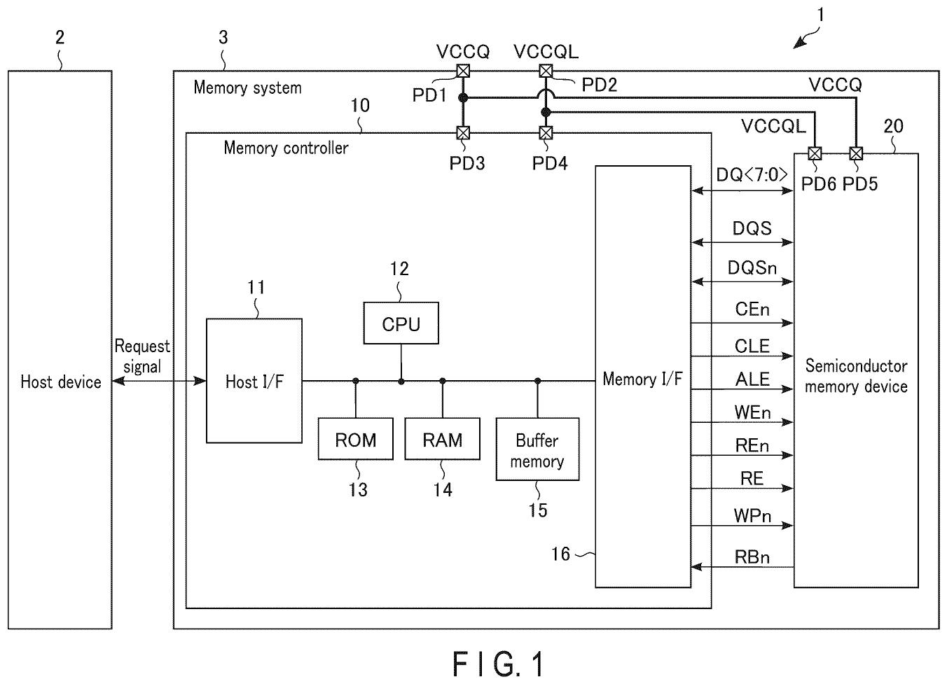

First, an example of a configuration of a data processing apparatus 1 will be described with reference to FIG. 1. FIG. 1 is a block diagram showing the overall configuration of the data processing apparatus 1. In the example of FIG. 1, some of the couplings between components are indicated by arrows, but the couplings between components are not limited to the arrows.

As shown in FIG. 1, the data processing apparatus 1 includes a host device 2 and a memory system 3. Note that a plurality of memory systems 3 may be coupled to the host device 2.

The host device 2 is an information processing device (computing device) that accesses the memory system 3. The host device 2 controls the memory system 3. More specifically, for example, the host device 2 requests (instructs) the memory system 3 to perform a data write operation or a data read operation.

The memory system 3 is, for example, a solid state drive (SSD). The memory system 3 is coupled to the host device 2. The memory system 3 includes electrode pads PD1 and PD2. The memory system 3 is supplied with voltages VCCQ and VCCQL from an external device (e.g., the host device 2) via the electrode pads PD1 and PD2, respectively. The voltage VCCQ is a power supply voltage of the memory system 3. The voltage VCCQL is a voltage for use in controlling a communication system (also referred to as “interface mode”) between the memory controller 10 and the semiconductor memory device 20. The memory system 3 selects an interface mode based on the voltage value of the voltage VCCQL.

More specifically, the memory system 3 is capable of selecting either a low tapped termination (LTT) mode or a power isolated (PI) LTT mode as the interface mode. LTT is a termination scheme similar to low voltage swing terminated logic (LVSTL) that is one of DRAM interface standards. The LVSTL is, for example, a standard adopted in low power double data rate 4 (LPDDR4). The PI LTT is a termination scheme similar to power isolated low voltage swing terminated logic (PI LVSTL) that is one of DRAM interface standards. The PI LVSTL is a standard adopted, for example, in LPDDR4X or LPDDR5. The amplitude of a signal in the PI LTT is smaller than that of a signal in the LTT. In addition, the upper limit value of the signal amplitude in the PI LTT is smaller than that in the LTT and thus the power consumption in the PI LTT is lower than that in the LTT. Thus, the PI LTT is more suitable for high-speed communication than the LTT. Therefore, the PI LTT can be employed in a next-generation product that employs the LTT.

If the voltage VCCQL is equal to or higher than a determination voltage value to be described later, the memory system 3 selects the LTT mode. If the voltage VCCQL is lower than the determination voltage value, the memory system 3 selects the PI LTT mode. Below is a description of a case where the voltage value of the voltage VCCQL is voltage VCCQ or voltage VCCQ/2. The memory system 3 selects the LTT mode if VCCQL is equal to VCCQ and selects the PI LTT mode if VCCQL is equal to VCCQ/2.

### 1.1.2 Configuration of Memory System

Referring to FIG. 1 again, an example of the configuration of the memory system 3 will be described.

As shown in FIG. 1, the memory system 3 includes a memory controller 10 and a semiconductor memory device 20. Note that the memory system 3 may include a plurality of semiconductor memory devices 20. In this case, the memory system 3 may include an interface circuit that couples the memory controller 10 and the plurality of semiconductor memory devices 20.

In response to a request (instruction) from the host device 2, the memory controller 10 instructs the semiconductor memory device 20 to perform a read operation, a write operation, an erase operation and the like. The memory controller 10 also manages the memory space of the semiconductor memory device 20. The memory controller 10 includes electrode pads PD3 and PD4. The memory controller 10 is supplied with voltages VCCQ and VCCQL via the electrode pads PD3 and PD4, respectively.

The semiconductor memory device 20 is, for example, a NAND flash memory. The NAND flash memory includes a plurality of memory cell transistors (also referred to as “memory cells” hereinafter) which store data nonvolatilely. The semiconductor memory device 20 includes electrode pads PD5 and PD6. The semiconductor memory device 20 is supplied with voltages VCCQ and VCCQL via the electrode pads PD5 and PD6, respectively.

Next is a description of the internal configuration of the memory controller 10. The memory controller 10 includes a host interface circuit (host I/F) 11, a central processing unit (CPU) 12, a read only memory (ROM) 13, a random access memory (RAM) 14, a buffer memory 15, and a memory interface circuit (memory I/F) 16. These circuits are coupled to each other via an internal bus, for example. Note that each function of the memory controller 10 may be fulfilled by a dedicated circuit or by the CPU 12 executing firmware (or programs).

The host interface circuit 11 is a hardware interface circuit coupled to the host device 2. The host interface circuit 11 performs communications that comply with an interface standard between the host device 2 and the memory controller 10. The host interface circuit 11 receives a request and data from the host device 2 and transmits the request and data to the CPU 12 and the buffer memory 15, respectively. The host interface circuit 11 also transmits data to the host device 2.

The CPU 12 is a processor. The CPU 12 controls the operation of the entire memory controller 10. For example, the CPU 12 instructs the semiconductor memory device 20 to perform a write operation, a read operation, and an erase operation based on the request received from the host device 2. The CPU 12 also manages the memory area of the semiconductor memory device 20.

The ROM 13 is a nonvolatile memory. The ROM 13 is, for example, an electrically erasable programmable read-only memory (EEPROM™). The ROM 13 is a non-transitory storage medium that stores firmware, programs and the like. For example, the operation of the memory controller 10 to be described later is carried out by the CPU 12 executing the firmware of the ROM 13.

The RAM 14 is a volatile memory. The RAM 14 is, for example, a dynamic random access memory (DRAM) or a static random access memory (SRAM). The RAM 14 is used as a work area of the CPU 12. The RAM 14 holds firmware for managing the semiconductor memory device 20, a variety of management tables, and the like.

The buffer memory 15 is a volatile memory. The buffer memory 15 is, for example, a DRAM or an SRAM. The buffer memory 15 temporarily holds data read from the semiconductor memory device 20 by the memory controller 10, data received from the host device 2, and the like.

The memory interface circuit 16 is a hardware interface circuit coupled to the semiconductor memory device 20. Voltages VCCQ and VCCQL are applied to the memory interface circuit 16. The memory interface circuit 16 selects either the LTT mode or the PI LTT mode based on the voltage value of the voltage VCCQL.

The memory interface circuit 16 transmits and receives data and various control signals to and from the semiconductor memory device 20. More specifically, the memory interface circuit 16 transmits and receives, for example, an 8-bit signals DQ<7:0> and clock signals DQS and DOSn to and from the semiconductor memory device 20. The signal DQ<7:0> is, for example, data, an address, and a command. Hereinafter, the signals DQ<7:0> will be referred to as signal DQ if it is not limited to one of signals DQ<7:0>. The clock signals DQS and DQSn are clock signals for use in inputting and outputting data. The clock signal DQSn is an inverted signal of the clock signal DQS.

In addition, the memory interface circuit 16 transmits a chip enable signal CEn, a command latch enable signal CLE, an address latch enable signal ALE, a write enable signal WEn, read enable signals RE and Ren, and a write protect signal WPn to the semiconductor memory device 20 as control signals. Then, the memory interface circuit 16 receives a ready/busy signal RBn from the semiconductor memory device 20.

The chip enable signal CEn is a signal to enable the semiconductor memory device 20. The signal CEn is asserted at a low (“L”) level, for example.

The command latch enable signal CLE is a signal indicating that the signal DQ is a command. The signal CLE is asserted at a high (“H”) level, for example.

The address latch enable signal ALE is a signal indicating that the signal DQ is an address. The signal ALE is asserted at the “H” level, for example. The write enable signal WEn is a signal to take the received signal in the semiconductor memory device 20. The signal WEn is asserted, for example, at the “L” level when the semiconductor memory device 20 captures a command and an address. Thus, the command and address are captured by the semiconductor memory device 20 each time the signal WEn is toggled.

The read enable signals RE and REn are signals to read data from the semiconductor memory device 20 by the memory controller 10. The signal REn is an inverted signal of the signal RE. For example, the semiconductor memory device 20 generates signals DOS and DOSn based on the signals RE and REn when it outputs data.

The write protect signal WPn is a signal to provide an instruction to inhibit the write operation. The signal WPn is asserted at the “L” level, for example.

The ready/busy signal RBn is a signal indicating whether the semiconductor memory device 20 is capable of receiving the signal DQ from the memory controller or not. The ready/busy signal RBn is set at the “L” level when the semiconductor memory device 20 is in a busy state, for example.

### 1.1.3 Configuration of Semiconductor Memory Device

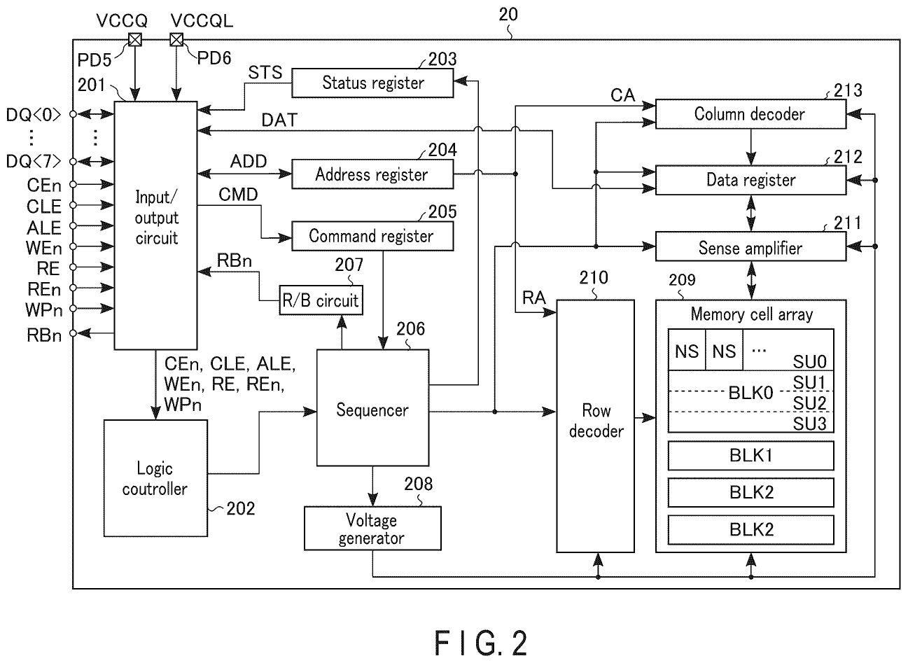

An example of a configuration of the semiconductor memory device 20 will be described below with reference to FIG. 2. In the example of FIG. 2, some of the couplings between components are indicated by arrows. However, the couplings between components are not limited to the arrows.

As shown in FIG. 2, the semiconductor memory device 20 includes an input/output circuit 201, a logic controller 202, a status register 203, an address register 204, a command register 205, a sequencer 206, a ready/busy circuit (R/B circuit) 207, a voltage generator 208, a memory cell array 209, a row decoder 210, a sense amplifier 211, a data register 212, and a column decoder 213.

The input/output circuit 201 receives a variety of signals and transmits them. Voltages VCCQ and VCCQL are applied to the input/output circuit 201. The input/output circuit 201 selects either an LTT mode or a PI LTT mode based on the voltage value of the voltage VCCQL. The input/output circuit 201 transmits and receives data and various control signals to and from the memory controller 10 based on the selected mode.

The input/output circuit 201 is coupled to the memory interface circuit 16 of the memory controller 10. The input/output circuit 201 is also coupled to the logic controller 202, the status register 203, the address register 204, the command register 205, the ready/busy circuit 207, and the data register 212. The input/output circuit 201 receives an input signal DQ based on clock signals DOS and DOSn if the input signal DQ is data DAT. Then, the input/output circuit 201 transmits the data DAT to the data register 212. The input/output circuit 201 transmits an output signal DQ to the memory controller 10 together with the clock signals DQS and DOSn if the output signal DQ is data DAT or status information STS. If the input signal DQ is an address ADD, the input/output circuit 201 transmits the address ADD to the address register 204. If the input signal DQ is a command CMD, the input/output circuit 201 transmits the command CMD to the command register 205. The input/output circuit 201 transmits input signals CEn, CLE, ALE, WEn, RE, Ren, and WPn to the logic controller 202. The input/output circuit 201 outputs the ready/busy signal RBn received from the ready/busy circuit 207 to the memory controller 10.

The logic controller 202 performs logic control. The logic controller 202 receives signals CEn, CLE, ALE, WEn, RE, REn and WPn from the input/output circuit 201. The logic controller 202 is coupled to the input/output circuit 201 and the sequencer 206. The logic controller 202 controls the sequencer 206 based on the received signal.

The status register 203 temporarily stores status information STS. The status information STS includes status information in a write operation, a read operation, an erase operation, and the like. The status register 203 is coupled to the input/output circuit 201 and the sequencer 206. The status register 203 receives the status information STS from the sequencer 206. The status information STS is transmitted to the memory controller 10 via the input/output circuit 201.

The address register 204 temporarily stores the address ADD. The address register 204 is coupled to the input/output circuit 201, the row decoder 210, and the column decoder 213. The address ADD includes a row address RA and a column address CA. The address register 204 transmits the row address RA to the row decoder 210. The address register 204 also transmits the column address CA to the column decoder 213.

The command register 205 temporarily stores the command CMD. The command register 205 is coupled to the input/output circuit 201 and the sequencer 206. The command register 205 transmits the command CMD to the sequencer 206.

The sequencer 206 is a circuit that controls the entire operation of the semiconductor memory device 20. The sequencer 206 is coupled to the logic controller 202, the status register 203, the command register 205, the ready/busy circuit 207, the voltage generator 208, the row decoder 210, the sense amplifier 211, the data register 212, the column decoder 213, and the like. The sequencer 206 controls the status register 203, the ready/busy circuit 207, the voltage generator 208, the row decoder 210, the sense amplifier 211, the data register 212, the column decoder 213, and the like. The sequencer 206 performs a write operation, a read operation, and an erase operation based on the command CMD.

The ready/busy circuit 207 is a circuit that generates a ready/busy signal RBn. The ready/busy circuit 207 is coupled to the input/output circuit 201 and the sequencer 206. The ready/busy circuit 207 generates a ready/busy signal RBn under the control of the sequencer 206. The ready/busy circuit 207 transmits the ready/busy signal RBn to the input/output circuit 201.

The voltage generator 208 generates a variety of voltages for use in a write operation, a read operation, and an erase operation under the control of the sequencer 206. The voltage generator 208 supplies a variety of voltages to the memory cell array 209, the row decoder 210, the sense amplifier 211, the data register 212, the column decoder 213, and the like.

The memory cell array 209 is a set of arrayed memory cell transistors. The memory cell array 209 includes a plurality of blocks BLK. The blocks BLK is, for example, a set of memory cell transistors for which data are collectively erased. In the example of FIG. 2, the memory cell array 209 includes four blocks BLK0, BLK1, BLK2, and BLK3. The number of blocks BLK in the memory cell array 209 is discretionarily.

Each of the blocks BLK includes a plurality of string units SU. The string unit SU is, for example, a set of NAND strings NS selected collectively in a write operation or a read operation. In the example of FIG. 2, each of the blocks BLK includes four string units SU0 to SU3. Note that the number of string units SU included in each block BLK is discretionarily.

Each of the NAND strings NS includes a plurality of memory cell transistors coupled in series. The details of the NAND strings will be described later.

The row decoder 210 is a decoding circuit of the row address RA. The row decoder 210 is coupled to the address register 204, the sequencer 206, the voltage generator 208, and the memory cell array 209. The row decoder 210 selects one of the blocks BLK based on the decoding result. The row decoder 210 applies voltages to interconnects (word lines and select gate lines to be described later) in the row direction of the selected one of the blocks BLK.

The sense amplifier 211 is a circuit that writes and reads data DAT. The sense amplifier 211 is coupled to the sequencer 206, the voltage generator 208, the memory cell array 209, and the data register 212. In a read operation, the sense amplifier 211 reads data DAT from the memory cell array 209. In a write operation, the sense amplifier 211 supplies voltages corresponding to the write data DAT to the memory cell array 209.

The data register 212 temporarily stores the data DAT. The data register 212 is coupled to the input/output circuit 201, the sequencer 206, the voltage generator 208, the sense amplifier 211, and the column decoder 213. The data register 212 includes a plurality of latch circuits. Each of the latch circuits temporarily stores write data or read data.

The column decoder 213 is a circuit that decodes the column address CA. The column decoder 213 is coupled to the address register 204, the sequencer 206, the voltage generator 208, and the data register 212. The column decoder 213 receives the column address CA from the address register 204. The column decoder 213 selects latch circuits in the data register 212 based on the decoding result of the column address CA.

### 1.1.4 Circuit Configuration of Memory Cell Array

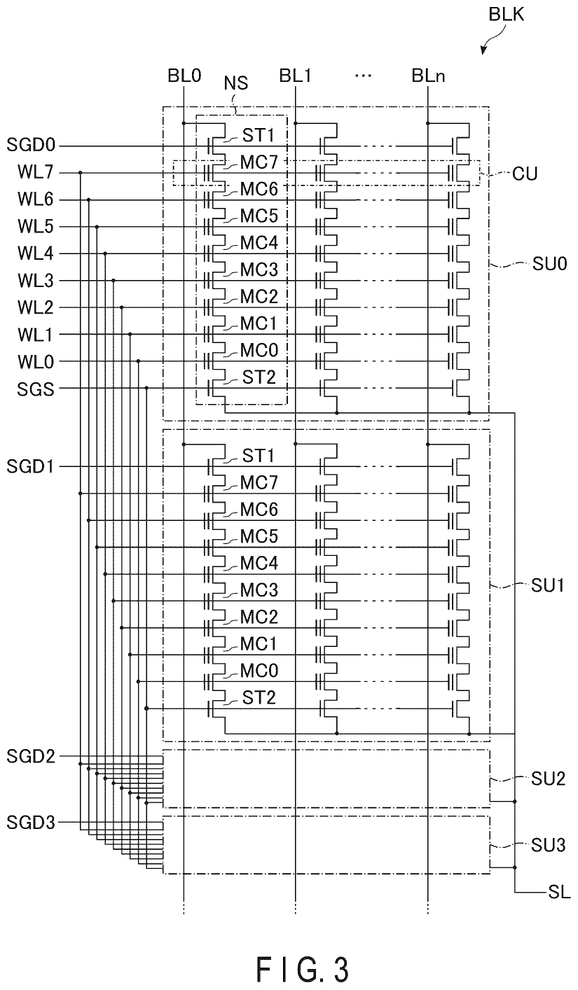

An example of a circuit configuration of the memory cell array 209 will be described below with reference to FIG. 3. FIG. 3 is a circuit diagram of the memory cell array 209. The example of FIG. 3 indicates to a circuit configuration of one block BLK.

As shown in FIG. 3, the block BLK includes, for example, four string units SU0, SU1, SU2, and SU3. Each string unit SU includes a plurality of NAND strings NS. For example, n+1 (n is an integer equal to or larger than 1) NAND strings NS in the string unit SU are coupled to their respective n+1 bit lines BL0 to BLn.

Each NAND string NS includes a plurality of memory cell transistors MC and selection transistors ST1 and ST2. In the example of FIG. 3, the NAND string NS includes eight memory cell transistors MC0 to MC7. Note that the number of memory cell transistors MC in the NAND string NS is discretionarily.

The memory cell transistors MC hold data nonvolatilely. Each of the memory cell transistors MC includes a control gate and a charge storage layer. The memory cell transistors MC may be of a metal-oxide-nitride-oxide-silicon (MONOS) type or a floating gate (FG) type. In the MONOS type, an insulating layer is used for the charge storage layer. In the FG type, a conductor layer is used for the charge storage layer.

The selection transistors ST1 and ST2 are used to select a string unit SU in a variety of operations. The number of selection transistors ST1 and ST2 is discretionarily. It suffices that each NAND string NS contains one or more select transistors ST1 and one or more select transistors ST2.

The current paths of the memory cell transistors MC and selection transistors ST1 and ST2 in each NAND string NS are coupled in series. More specifically, the current paths are coupled in series in the order presented as follows: the selection transistor ST2, memory cell transistors MC0 to MC7 and selection transistor ST1. A drain of the selection transistor ST1 is coupled to one of the bit lines BL. A source of the selection transistor ST2 is coupled to a source line SL.

The control gates of the memory cell transistors MC0 to MC7 in the same block BLK are coupled in common to their respective word lines WL0 to WL7. More specifically, for example, the block BLK includes four string units SU0 to SU3. The string units SU0 to SU3 each include a plurality of memory cell transistors MC0. The control gates of the memory cell transistors MC0 in the block BLK are coupled in common to one word line WL0. The same applies to the memory cell transistors MC1 to MC7.

Gates of the selection transistors ST1 in the string unit SU are coupled in common to one select gate line SGD. More specifically, the string unit SU0 includes a plurality of selection transistors ST1. The gates of the selection transistors ST1 in the string unit SU0 are coupled in common to the select gate line SGD0. Similarly, the gates of the selection transistors ST1 in the string unit SU1 are coupled in common to the select gate line SGD1. The gates of the selection transistors ST1 in the string unit SU2 are coupled in common to the select gate line SGD2. The gates of the selection transistors ST1 in the string unit SU3 are coupled in common to the select gate line SGD3.

Gates of the selection transistors ST2 in the same block BLK are coupled in common to one select gate line SGS. More specifically, for example, the block BLK includes four string units SU0 to SU3. The string units SU0 to SU3 each include a plurality of selection transistors ST2. The gates of the selection transistors ST2 in the block BLK are coupled in common to one select gate line SGS. Like the select gate line SGD, a different selection gate line SGS may be provided for each string unit SU.

The word lines WL0 to WL7, the select gate lines SGD0 to SGD3, and the select gate line SGS are each coupled to the row decoder 210.

Each bit line BL is coupled to one NAND string NS in each string unit SU of each block BLK. The same column address CA is assigned to a plurality of NAND strings NS coupled to one bit line BL. Each bit line BL is coupled to the sense amplifier 211.

The source line SL is shared among a plurality of blocks BLK, for example.

A set of memory cell transistors MC coupled to one word line WL in one string unit SU is represented, for example, as “cell unit CU.” For example, if the memory cell transistor MC stores 1-bit data, the storage capacity of the cell unit CU is defined as “1 page data.” Based on the number of bits of data stored in the memory cell transistor MC, the cell unit CU may have a storage capacity of data of two or more pages.

### 1.1.5 Configuration of Memory Interface Circuit

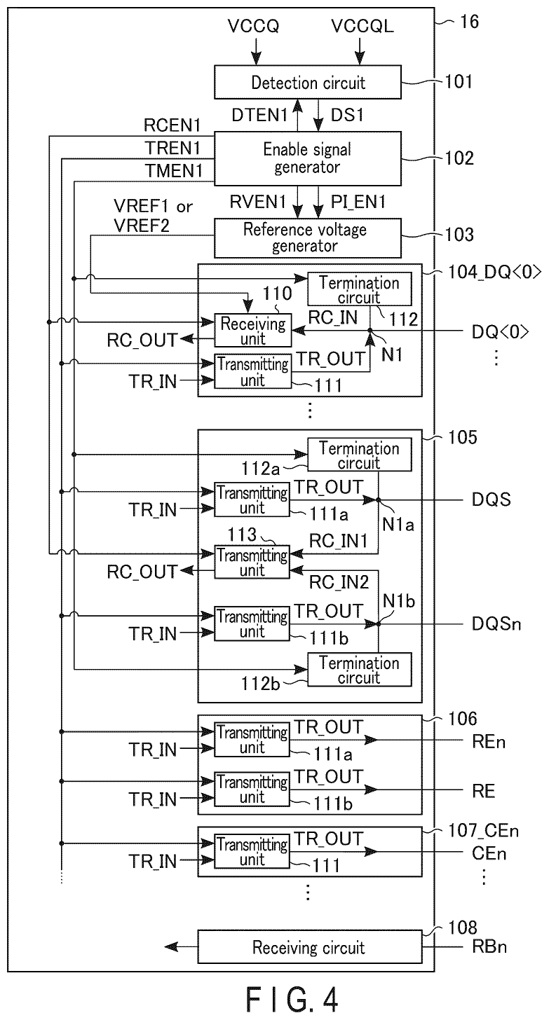

An example of a configuration of the memory interface circuit 16 will be described below with reference to FIG. 4. FIG. 4 is a block diagram of the memory interface circuit 16. The example of FIG. 4 will be described with attention to components related to the transmission and reception of signals between the memory interface circuit 16 and the semiconductor memory device 20 (input/output circuit 201). In the example of FIG. 4, for simplicity, components corresponding to signals DQ<0>, DOS, DQSn, REn, RE, CEn, and RBn are shown and components corresponding to signals DQ<7:1>, CLE, ALE, WEn, and WPn are omitted. For example, the components corresponding to the signals DQ<7:1> are similar to the component corresponding to the signal DQ<0>. For example, the components corresponding to the signals CLE, ALE, WEn and WPn are similar to the component corresponding to the signal CEn.

As shown in FIG. 4, the memory interface circuit 16 includes a detection circuit 101, an enable signal generator 102, a reference voltage generator 103, a plurality of transmit/receive circuits 104, a transmit/receive circuit 105, a transmitting circuit 106, a plurality of transmitting circuits 107, and a receiving circuit 108.

The detection circuit 101 detects the voltage VCCQL. The detection circuit 101 is supplied with voltages VCCQ and VCCQL. The detection circuit 101 is coupled to the enable signal generator 102. If the detection circuit 101 receives, for example, the “H” level enable signal DTEN1 from the enable signal generator 102, it transmits a detection signal DS1 to the enable signal generator 102. If the detection circuit 101 is enabled, the signal DTEN1 is set, for example, at the “H” level.

If the voltage VCCQL is, for example, equal to or higher than a preset determination voltage value, the detection circuit 101 transmits the “L” level signal DS1 to the enable signal generator 102. If the voltage VCCQL is lower than the determination voltage value, the detection circuit 101 transmits the “H” level signal DS1 to the enable signal generator 102. The “L” level signal DS1 corresponds to the LTT mode, and the “H” level signal DS1 corresponds to the PI LTT mode. In other words, the detection circuit 101 functions as a selection circuit that selects the LTT mode or the PI LTT mode based on the voltage value of the voltage VCCQL.

The enable signal generator 102 is a circuit that generates a variety of enable signals. The enable signal generator 102 is coupled to the detection circuit 101, the reference voltage generator 103, the transmit/receive circuits 104 and 105, and the transmitting circuits 106 and 107. The enable signal generator 102 generates signals DTEN1, RVEN1, PI_EN1, RCEN1, TREN1, and TMEN1 under the control of the CPU 12. The enable signal generator 102 transmits the signal DTEN1 to the detection circuit 101. The enable signal generator 102 transmits the signals RVEN1 and PI_EN1 to the reference voltage generator 103. The enable signal generator 102 transmits the signal RCEN1 to a receiving unit 110 of the transmit/receive circuit 104, and a receiving unit 113 of the transmit/receive circuit 105. The enable signal generator 102 transmits the signal TMEN1 to a termination circuit 112 of the transmit/receive circuit 104 and termination circuits 112a and 112b of the transmit/receive circuit 105. The enable signal generator 102 transmits the signal TREN1 to transmitting units 111 of the transmit/receive circuit 104 and the transmitting circuit 107, and to transmitting units 111a and 111b of the transmit/receive circuit 105 and the transmitting circuit 106.

The signal RVEN1 is a signal that enables the reference voltage generator 103. The signal RVEN1 is set at, for example, the “H” level if the reference voltage generator 103 is enabled.

The signal PI_EN1 is a signal based on the interface mode. The signal PI_EN1 is set at, for example, the “L” level if the LTT mode is selected. On the other hand, the signal PI_EN1 is set at the “H” level if the PI LTT mode is selected.

The signal RCEN1 is a signal that enables the receiving units 110 and 113. The signal RCEN1 is set at, for example, the “H” level if a signal is received from the semiconductor memory device 20.

The signal TREN1 is a signal that enables the transmitting units 111, 111a and 111b. The signal TREN1 is at, for example, the “H” level if a signal is transmitted to the semiconductor memory device 20.

The signal TMEN1 is a signal that enables the termination circuits 112, 112a and 112b. The signal TMEN1 is set at, for example, the “H” level if the termination circuits 112, 112a and 112b are enabled.

The reference voltage generator 103 is a circuit that generates a reference voltage to be supplied to the receiving unit 110. The reference voltage generator 103 is coupled to the enable signal generator 102 and the receiving unit 110 of the transmit/receive circuit 104. The reference voltage generator 103 generates a reference voltage VREF1 or a reference voltage VREF2 based on the signal RVEN1 and the signal PI_EN1. For example, the reference voltage generator 103 generates the reference voltage VREF1 if the signal RVEN1 is at the “H” level and the signal PI_EN1 is at the “L” level. The reference voltage VREF1 is a reference voltage corresponding to the LTT mode. For example, the reference voltage generator 103 also generates the reference voltage VREF2 if the signal RVEN1 is at the “H” level and the signal PI_EN1 is at the “H” level. The reference voltage VREF2 is a reference voltage corresponding to the PI LTT mode.

The transmit/receive circuit 104 transmits and receives the signal DQ to and from the semiconductor memory device 20. The memory interface circuit 16 includes, for example, eight transmit/receive circuits 104 each corresponding to the signals DQ<7:0>. The configurations of the transmit/receive circuits 104 are the same. If a transmit/receive circuit 104 corresponding to the signal DQ<0> is limited, it will be referred to as a transmit/receive circuit 104_DQ<0> hereinafter. The same applies to the transmit/receive circuits 104 corresponding to the signals DQ<7:1>. FIG. 4 shows, for example, a transmit/receive circuit 104_DQ<0> corresponding to the signal DQ<0>.

The transmit/receive circuit 104 includes a receiving unit 110, a transmitting unit 111, and a termination circuit 112.

The transmit/receive circuit 105 is a circuit that transmits and receives signals DOS and DQSn to and from the semiconductor memory device 20. The configuration of the transmit/receive circuit 105 differs from that of the transmit/receive circuit 104. The transmit/receive circuit 105 includes transmitting units 111a and 111b, termination circuits 112a and 112b, and receiving unit 113.

The transmitting circuit 106 is a circuit that transmits signals REn and RE to the semiconductor memory device 20. The transmitting circuit 106 includes transmitting units 111a and 111b. The transmitting circuit 106 is a circuit in which the receiving unit 113 and the termination circuits 112a and 112b are excluded from the transmit/receive circuit 105.

The transmitting circuit 107 is a circuit that transmits a signal to the semiconductor memory device 20. For example, the memory interface circuit 16 includes five transmitting circuits 107 corresponding to their respective signals CEn, CLE, ALE, WEn, and WPn. The configurations of the transmitting circuits 107 are the same. If, for example, a transmitting circuit 107 corresponding to the signal CEn is limited, it will be referred to as a transmitting circuit 107 CEn hereinafter. For example, FIG. 4 shows a transmitting circuit 107 CEn corresponding to the signal CEn.

The transmitting circuits 107 each includes a transmitting unit 111. The configuration of the transmitting unit 111 is similar to that of the transmitting unit 111 of the transmit/receive circuit 104. In other words, each of the transmitting circuits 107 is a circuit in which the receiving unit 110 and the termination circuit 112 are excluded from the transmit/receive circuit 104.

The receiving circuit 108 is a circuit that receives the signal RBn from the semiconductor memory device 20.

The receiving unit 110 is a circuit that receives a signal from the semiconductor memory device 20. For example, the receiving unit 110 included in the transmit/receive circuit 104_DQ<0> receives the signal DQ<0> input from the semiconductor memory device 20 as an input signal RC_IN, and outputs an output signal RC_OUT to one of the internal circuits of the memory controller 10. The receiving unit 110 is coupled to a node N1. The node N1 is coupled to the input/output circuit 201 of the semiconductor memory device 20. For example, the receiving unit 110 is enabled if the signal RCEN1 is at the “H” level. The receiving unit 110 compares the input signal RC_IN from the semiconductor memory device 20 and the reference voltage VREF1 or VREF2. Based on a result of the comparison, the receiving unit 110 determines the logical level (“L”/“H” level) of the input signal RC_IN. The receiving unit 110 converts the input signal RC_IN into an appropriate voltage level for processing in the memory controller 10. Then, the receiving unit 110 outputs the output signal TR_OUT to one of the internal circuits of the memory controller 10. More specifically, if the signal RCEN1 is, for example, at the “H” level, the receiving unit 110 of the transmit/receive circuit 104_DQ<0> receives the signal DQ<0> from the semiconductor memory device 20 as the input signal RC_IN. In the LTT mode, the receiving unit 110 of the transmit/receive circuit 104_DQ<0> compares the signal DQ<0> (input signal RC_IN) and the reference voltage VREF1. On the other hand, in the PI LTT mode, the receiving unit 110 of the transmit/receive circuit 104_DQ<0> compares the signal DQ<0> and the reference voltage VREF2. The receiving unit 110 of the transmit/receive circuit 104_DQ<0> determines the logical level of the signal DQ<0> based on a result of the comparison. The receiving unit 110 converts the voltage level of the signal DQ<0>. Then, the receiving unit 110 of the transmit/receive circuit 104_DQ<0> transmits the signal DQ<0> as an output signal RC_OUT to one of the internal circuits of the memory controller 10.

The transmitting unit 111 is a circuit that transmits a signal to the semiconductor memory device 20. For example, the transmitting unit 111 included in the transmit/receive circuit 104_DQ<0> receives an input signal TR_IN from one of the internal circuits of the memory controller 10, and outputs an output signal TR_OUT to the semiconductor memory device 20 as the signal DQ<0>. The transmitting unit 111 is coupled to the node N1. The transmitting unit 111 is supplied with a voltage VCCQL. For example, the transmitting unit 111 is enabled if the signal TREN1 is, for example, at the “H” level. The transmitting unit 111 receives an input signal TR_IN from one of the internal circuits (e.g., buffer memory 15) of the memory controller 10. The transmitting unit 111 transmits a signal TR_OUT corresponding to a mode based on the voltage VCCQL to the semiconductor memory device 20. More specifically, for example, the transmitting unit 111 of the transmit/receive circuit 104_DQ<0> outputs the signal DQ<0> corresponding to the LTT mode as an output signal TR_OUT if the voltage VCCQL is equal to VCCQ. For example, the transmitting unit 111 of the transmit/receive circuit 104_DQ<0> also outputs the signal DQ<0> corresponding to the PI LTT mode as an output signal TR_OUT if the voltage VCCQL is equal to VCCQ/2.

The transmitting units 111a and 111b are circuits that transmit a signal to the semiconductor memory device 20. For example, the transmitting unit 111a of the transmit/receive circuit 105 transmits the signal DQS to the semiconductor memory device 20. The transmitting unit 111b of the transmit/receive circuit 105 transmits the signal DOSn to the semiconductor memory device 20. The transmitting unit 111a of the transmitting circuit 106 transmits the signal REn to the semiconductor memory 20. The transmitting unit 111b of the transmitting circuit 106 transmits the signal RE to the semiconductor memory device 20. The configuration of each of the transmitting units 111a and 111b is similar to that of the transmitting unit 111. The transmitting unit 111a of the transmit/receive circuit 105 is coupled to a node N1a. The transmitting unit 111b of the transmit/receive circuit 105 is coupled to a node N1b. The nodes N1a and N1b are coupled to the input/output circuit 201 of the semiconductor memory device 20. The transmitting units 111a and 111b are supplied with a voltage VCCQL. The transmitting units 111a and 111b are enabled if the signal TREN1 is, for example, at the “H” level. If a transmitting unit is limited to neither of the transmitting units 111a and 111b, it will simply be referred to as a transmitting unit 111 hereinafter.

The termination circuit 112 is a circuit that terminates a reflection of a signal generated between the termination circuit 112 and its outside (in this case, the semiconductor memory device 20) when it transmits and receives the signal. The termination circuit 112 is coupled to the node N1. The termination circuit 112 is enabled if the signal TMEN1 is at the “H” level. If the signal RCEN1 is, for example, at the “H” level, the signal TMEN1 is set at the “H” level. That is, the termination circuit 112 performs a termination process if the receiving unit 110 receives a signal.

The termination circuit 112a is a circuit that terminates a reflection of the signal DQS. The termination circuit 112b is a circuit that terminates a reflection of the signal DOSn. The configuration of each of the termination circuits 112a and 112b is similar to that of the termination circuit 112. The termination circuit 112a is coupled to the node N1a. The termination circuit 112b is coupled to the node N1b. The termination circuits 112a and 112b are enabled if the signal TMEN1 is at the “H” level. If a termination circuit is limited to neither of the termination circuits 112a and 112b, it will simply be referred to as a termination circuit 112 hereinafter.

The receiving unit 113 is a circuit that receives signals DOS and DOSn from the semiconductor memory device 20. For example, the receiving unit 113 receives the signal DQS as an input signal RC_IN1 and receives the signal DOSn as an input signal RC_IN2. Then, the receiving unit 113 outputs the output signal RC_OUT based on a difference in voltage between the signal DQS and the signal DOSn to one of the internal circuits of the memory controller 10. One input terminal of the receiving unit 113 that receives the signal RC_IN1 is coupled to the node N1a. The other input terminal of the receiving unit 113 that receives the signal RC_IN2 is coupled to the node N1b. For example, the receiving unit 113 is enabled if the signal RCEN1 is, for example, at the “H” level. The receiving unit 113 determines the logical level of the output signal RC_OUT based on a difference in voltage between the signal DQS and the signal DQSn. The receiving unit 113 converts the output signal RC_OUT into an appropriate voltage level for processing in the memory controller 10. Then, the receiving unit 113 outputs the output signal RC_OUT to one of the internal circuits of the memory controller 10.

### 1.1.6 Configuration of Input/Output Circuit

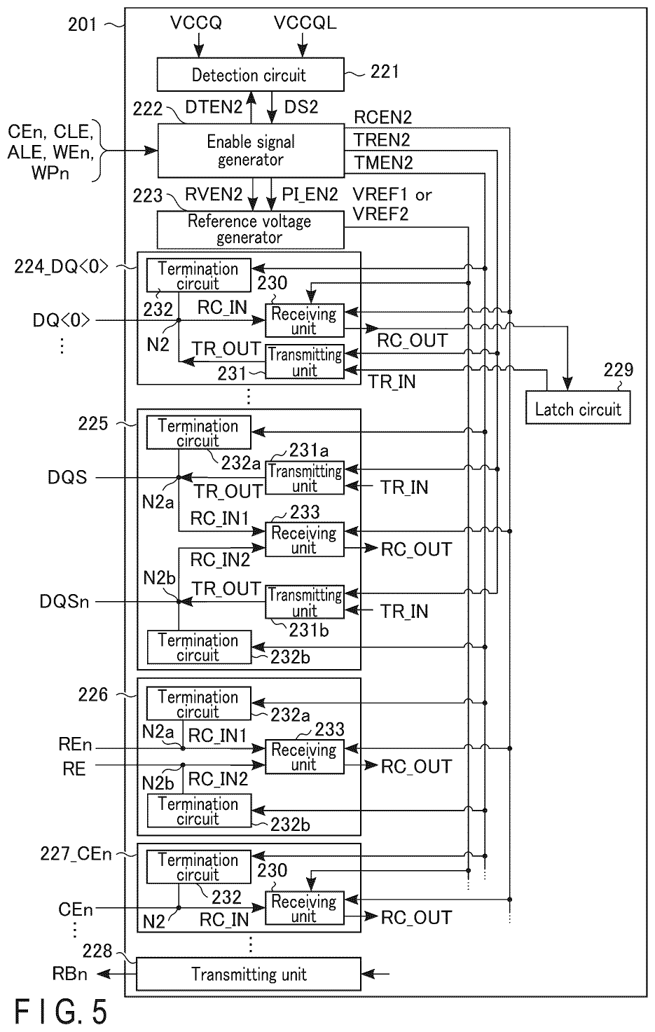

An example of a configuration of the input/output circuit 201 will be described with reference to FIG. 5. FIG. 5 is a block diagram of the input/output circuit 201. The example of FIG. 5 will be described with attention to components related to the transmission and reception of signals between the input/output circuit 201 and the memory controller 10 (memory interface circuit 16). In the example of FIG. 5, for simplicity, components corresponding to signals DQ<0>, DQS, DQSn, REn, RE, Cen, and RBn are shown, and components corresponding to signals DQ<7:1>, CLE, ALE, WEn, and WPn are omitted. For example, the components corresponding to the signals DQ<7:1> are similar to the component corresponding to the signal DQ<0>. For example, the components corresponding to the signals CLE, ALE, WEn, and WPn are similar to the component corresponding to the signal CEn.

As shown in FIG. 5, the input/output circuit 201 includes a detection circuit 221, an enable signal generator 222, a reference voltage generator 223, a plurality of transmit/receive circuits 224, a transmit/receive circuit 225, a receiving circuit 226, a plurality of receiving circuits 227, a transmitting circuit 228, and a plurality of latch circuits 229.

The detection circuit 221 is a circuit that detects the voltage VCCQL. The detection circuit 221 has a configuration similar to that of the detection circuit 101. The detection circuit 221 is supplied with voltages VCCQ and VCCQL. The detection circuit 221 is coupled to the enable signal generator 222. Upon receiving, for example, the “H” level signal DTEN2 from the enable signal generator 222, the detection circuit 221 transmits a detection signal DS2 to the enable signal generator 222. The signal DTEN2 is an enable signal of the detection circuit 221. If the detection circuit 221 is enabled, the signal DTEN2 is set, for example, at the “H” level.

If the voltage VCCQL is, for example, equal to or higher than a preset determination voltage, the detection circuit 221 transmits the “L” level signal DS2 to the enable signal generator 222. If the voltage VCCQL is lower than the determination voltage, the detection circuit 221 transmits the “H” level signal DS2 to the enable signal generator 222. The “L” level signal DS2 corresponds to the LTT mode, and the “H” level signal DS2 corresponds to the PI LTT mode. In other words, the detection circuit 221 functions as a selection circuit that selects the LTT mode or the PI LTT mode based on the value of the voltage VCCQL.

The enable signal generator 222 is a circuit that generates enable signals. The enable signal generator 222 is coupled to the detection circuit 221, the reference voltage generator 223, the transmit/receive circuits 224 and 225, and the receiving circuits 226 and 227. The enable signal generator 222 generates signals DTEN2, RVEN2, PI_EN2, RCEN2, TREN2, and TMEN2 based on the signals CEn, CLE, ALE, WEn, and WPn. The enable signal generator 222 transmits the signal DTEN2 to the detection circuit 221. The enable signal generator 222 transmits the signals RVEN2 and PI_EN2 to the reference voltage generator 223. The enable signal generator 222 transmits the signal RCEN2 to a receiving unit 230 of each of the transmit/receive circuit 224 and the receiving circuit 227 and to a receiving unit 233 of each of the transmit/receive circuit 225 and the receiving circuit 226. The enable signal generator 222 transmits the signal TMEN2 to a termination circuit 232 of each of the transmit/receive circuit 224 and the receiving circuit 227 and to termination circuits 232a and 232b of the transmit/receive circuit 225 and the receiving circuit 226. The enable signal generator 222 transmits the signal TREN2 to a transmitting unit 231 of the transmit/receive circuit 224 and transmitting units 231a and 231b of the transmit/receive circuit 225.

The signal RVEN2 is a signal that enables the reference voltage generator 223. If the reference voltage generator 223 is enabled, the signal RVEN2 is set, for example, at the “H” level.

The signal PI_EN2 is a signal based on the interface mode. If the LTT mode is selected, the signal PI_EN2 is set, for example, at the “L” level. On the other hand, if the PI LTT mode is selected, the signal PI_EN2 is set at the “H” level.

The signal RCEN2 is a signal that enables the receiving units 230 and 233. The signal RCEN2 is, for example, at the “H” level if a signal is received from the memory controller 10.

The signal TREN 2 is a signal that enables the transmitting units 231, 231a and 231b. The signal TREN 2 is set, for example, at the “H” level if a signal is transmitted to the memory controller 10.

The signal TMEN2 is a signal that enables the termination circuits 232, 232a and 232b. The signal TMEN2 is set, for example, at the “H” level if the termination circuits 232, 232a and 232b are enabled.

The reference voltage generator 223 is a circuit that generates a reference voltage to be supplied to the receiving unit 230. The reference voltage generator 223 is coupled to the enable signal generator 222, and the receiving unit 230 of each of the transmit/receive circuit 224 and receiving circuit 227. The reference voltage generator 223 generates a reference voltage VREF1 or VREF2 based on the signals RVEN2 and PI_EN2. For example, the reference voltage generator 223 generates the reference voltage VREF1 if the signal RVEN2 is at the “H” level and the signal PI_EN2 is at the “L” level. The reference voltage generator 223 also generates the reference voltage VREF2 if the signal RVEN2 is at the “H” level and the signal PI_EN2 is at the “H” level.

The transmit/receive circuit 224 is a circuit that transmits and receives a signal DQ to and from the memory controller 10. The input/output circuit 201 includes, for example, eight transmit/receive circuits 224 each corresponding to signals DQ<7:0>. The configurations of the transmit/receive circuits 224 are the same. The configuration of the transmit/receive circuit 224 is similar to that of the transmit/receive circuit 104. If a transmit/receive circuit 224 corresponding to the signal DQ<0> is limited, it will be referred to as a transmit/receive circuit 224_DQ<0> hereinafter. For example, FIG. 5 shows the transmit/receive circuit 224_DQ<0> corresponding to the signal DQ<0>.

The transmit/receive circuit 224 includes a receiving unit 230, a transmitting unit 231, and a termination circuit 232.

The transmit/receive circuit 225 is a circuit that transmits and receives signals DQS and DQSn to and from the memory controller 10. The configuration of the transmit/receive circuit 225 differs from that of the transmit/receive circuit 224. The transmit/receive circuit 225 includes transmitting units 231a and 231b, termination circuits 232a and 232b, and a receiving unit 233.

The receiving circuit 226 is a circuit that receives signals REn and RE from the memory controller 10. The receiving circuit 226 includes termination circuits 232a and 232b and a receiving unit 233. The configuration of each of the receiving unit 233 and termination circuits 232a and 232b is similar to that of the transmit/receive circuit 225. In other words, the receiving circuit 226 is a circuit in which the transmitting units 231a and 231b are excluded from the transmit/receive circuit 225.

The receiving circuit 227 is a circuit that receives a signal from the memory controller 10. The input/output circuit 201 includes, for example, five receiving circuits 227 corresponding to signals CEn, CLE, ALE, WEn, and WPn. The configurations of the receiving circuits 227 are the same. If a receiving circuit 227 corresponding to, for example, the signal CEn is limited, it will be referred to as a receiving circuit 227_CEn hereinafter. FIG. 5 shows, for example, a receiving circuit 227_CEn corresponding to the signal CEn.

The receiving circuit 227 includes the receiving unit 230 and the termination circuit 232. The configuration of each of the receiving unit 230 and termination circuit 232 is similar to that of the transmit/receive circuit 224. In other words, the receiving circuit 227 is a circuit in which the transmitting unit 231 is excluded from the transmit/receive circuit 224.

The transmitting circuit 228 is a circuit that transmits the signal RBn to the memory controller 10. For example, the transmitting circuit 228 is coupled to the ready/busy circuit 207.

The latch circuit 229 is a circuit that stores the signal DQ temporarily. The input/output circuit 201 includes, for example, eight latch circuits 229 each corresponding to the signals DQ<7:0>. The latch circuit 229 is coupled to the receiving unit 230 and transmitting unit 231 of the transmit/receive circuit 224 corresponding to any signal DQ. If the input signal DQ is, for example, data, the latch circuit 229 stores the signal DQ received from the receiving unit 230 based on the signals DOS and DOSn. In other words, if the input signal DQ is, for example, data, the latch circuit 229 stores the output signal RC_OUT of the receiving unit 230 of the transmit/receive circuit 224 based on the output signal RC_OUT of the receiving unit 233 of the transmit/receive circuit 225. If the input signal DQ is an address or a command, the latch circuit 229 stores the signal DQ received from the receiving unit 230 based on the signals RE and REn. In other words, if the input signal DQ is an address or a command, the latch circuit 229 stores the output signal RC_OUT of the receiving unit 230 of the transmit/receive circuit 224 based on the output signal RC_OUT of the receiving unit 233 of the receiving circuit 226. The latch circuit 229 also stores the signal DQ (e.g., status information STS or data DAT) received from the status register 203 or the data register 212, for example. Then, the latch circuit 229 transmits the signal DQ to the transmitting unit 231 of the transmit/receive circuit 224.

The receiving unit 230 is a circuit that receives a signal from the memory controller 10. The receiving unit 230 included, for example, in the transmit/receive circuit 224_DQ<0> receives the signal DQ<0> from the memory controller 10 as the input signal RC_IN and outputs the output signal RC_OUT to the latch circuit 229. The receiving unit 230 is coupled to a node N2. The node N2 is coupled to the memory interface circuit 16 of the memory controller 10. The receiving unit 230 is enabled if the signal RCEN2 is, for example, at the “H” level. The receiving unit 230 compares the input signal RC_IN received from the memory controller 10 and the reference voltage VREF1 or VREF2. Based on a result of the comparison, the receiving unit 230 determines the logical level of the input signal RC_IN. The receiving unit 230 outputs a signal whose logic level is determined. The receiving unit 230 converts the input signal RC_IN to an appropriate voltage level for processing in the semiconductor memory device 20. Then, the receiving unit 230 outputs the output signal RC_OUT to one of the internal circuits of the semiconductor memory device 20. More specifically, if the signal RCEN2 is, for example, at the “H” level, the receiving unit 230 of the transmit/receive circuit 224_DQ<0> receives the signal DQ<0> from the memory controller 10 as the input signal RC_IN. In the LTT mode, the receiving unit 230 of the transmit/receive circuit 224_DQ<0> compares the signal DQ<0> and the reference voltage VREF1. On the other hand, in the PI LTT mode, the receiving unit 230 of the transmit/receive circuit 224_DQ<0> compares the signal DQ<0> and the reference voltage VREF2. Based on a result of the comparison, the receiving unit 230 of the transmit/receive circuit 224_DQ<0> determines the logical level of the signal DQ<0>. The receiving unit 230 converts the voltage level of the signal DQ<0>. The receiving unit 230 of the transmit/receive circuit 224_DQ<0> transmits the signal DQ<0> to the latch circuit 229 as the output signal RC_OUT.

The transmitting unit 231 is a circuit that transmits a signal to the memory controller 10. The transmitting unit 231 included, for example, in the transmit/receive circuit 224_DQ<0> receives the input signal TR_IN from the latch circuit 229 and outputs the output signal TR_OUT as the signal DQ<0> to the memory controller 10. The transmitting unit 231 is coupled to the node N2. The transmitting unit 231 is supplied with the voltage VCCQL. If the signal TREN2 is, for example, at the “H” level, the transmitting unit 231 is enabled. The transmitting unit 231 receives an input signal TR_IN from one of the internal circuits (e.g., latch circuit 229) of the semiconductor memory device 20. The transmitting unit 231 transmits a signal TR_OUT corresponding to a mode based on the voltage VCCQL to the memory controller 10. More specifically, if the voltage VCCQL is, for example, equal to VCCQ, the transmitting unit 231 of the transmit/receive circuit 224_DQ<0> outputs the signal DQ<0> corresponding to the LTT mode as the output signal TR_OUT. If the voltage VCCQL is, for example, equal to VCCQ/2, the transmitting unit 231 of the transmit/receive circuit 224_DQ<0> outputs the signal DQ<0> corresponding to the PI LTT mode.

The transmitting unit 231a is a circuit that transmits a signal DOS to the memory controller 10. The transmitting unit 231b is a circuit that transmits a signal DOSn to the memory controller 10. The configuration of each of the transmitting units 231a and 231b is similar to that of the transmitting unit 231. The transmitting unit 231a is coupled to a node N2a. The transmitting unit 231b is coupled to a node N2b. The nodes N2a and N2b are coupled to the memory interface circuit 16 of the memory controller 10. The transmitting units 231a and 231b are supplied with the voltage VCCQL. The transmitting units 231a and 231b are enabled if the signal TREN2 is, for example, at the “H” level. If the transmitting unit 231a or 231b is not limited, it will simply be referred to as a transmitting unit 231 hereinafter.

The termination circuit 232 is a circuit that terminating a reflection of a signal generated between the termination circuit and its outside (in this case, the memory controller 10) when it receives and transmits the signal. The termination circuit 232 is coupled to the node N2. The termination circuit 232 is enabled if the signal TMEN2 is at the “H” level. If the signal RCEN2 is, for example, at the “H” level, the signal TMEN2 is set at the “H” level. That is, the termination circuit 232 performs a termination process if the receiving unit 230 receives a signal.

The termination circuits 232a and 232b are circuits that terminate a reflection of a signal generated between each of the termination circuits and its outside (in this case, the memory controller 10) when they receive and transmit the signal. For example, the termination circuit 232a of the transmit/receive circuit 225 terminates the reflection of the signal DQS. The termination circuit 232b of the transmit/receive circuit 225 terminates the reflection of the signal DQSn. The termination circuit 232a of the receiving circuit 226 terminates the reflection of the signal REn. The termination circuit 232b of the receiving circuit 226 terminates the reflection of the signal RE. The configuration of each of the termination circuits 232a and 232b is similar to that of the termination circuit 232. The termination circuit 232a is coupled to the node N2a. The termination circuit 232b is coupled to the node N2b. The termination circuits 232a and 232b are enabled if the signal TMEN2 is at the “H” level. If the transmitting unit 232a or 232b is not limited, it will simply be referred to as a transmitting unit 232 hereinafter.

The receiving unit 233 is a circuit that receives a signal from the memory controller 10. For example, the receiving unit 233 of the transmit/receive circuit 225 receives signals DQS and DOSn from the memory controller 10. For example, the receiving unit 233 of the transmit/receive circuit 225 receives the signal DQS as an input signal RC_IN1 and receives the signal DQSn as an input signal RC_IN2. Then, the receiving unit 233 of the transmit/receive circuit 225 outputs an output signal RC_OUT based on a difference in voltage between the signal DOS and the signal DQSn to one of the internal circuits of the semiconductor memory device 20. In addition, the receiving unit 233 of the receiving circuit 226 receives signals REn and RE from the memory controller 10. For example, the receiving unit 233 of the receiving circuit 226 receives the signal REn as the input signal RC_IN1 and receives the signal RE as the input signal RC_IN2. Then, the receiving unit 233 of the receiving circuit 226 outputs an output signal RC_OUT based on a difference in voltage between the signal REn and the signal RE to one of the internal circuits of the semiconductor memory device 20. One input terminal of the receiving unit 233 that receives the signal RC_IN1 is coupled to the node N2a. The other input terminal of the receiving unit 233 that receives the signal RC_IN2 is coupled to the node N2b. The receiving unit 233 is enabled if the signal RCEN2 is, for example, at the “H” level. The receiving unit 233 determines the logical level of the output signal RC_OUT based on the difference in voltage between the signal RE_IN1 and the signal RC_IN2. The receiving unit 233 converts the output signal RC_OUT into an appropriate voltage level for processing in the semiconductor memory device 20. Then, the receiving unit 230 outputs the output signal RC_OUT to one of the internal circuits of the semiconductor memory device 20.

### 1.1.7 Configuration of Detection Circuit

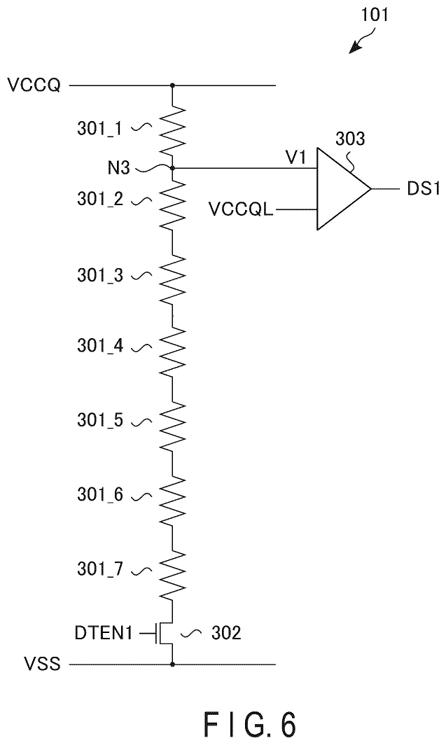

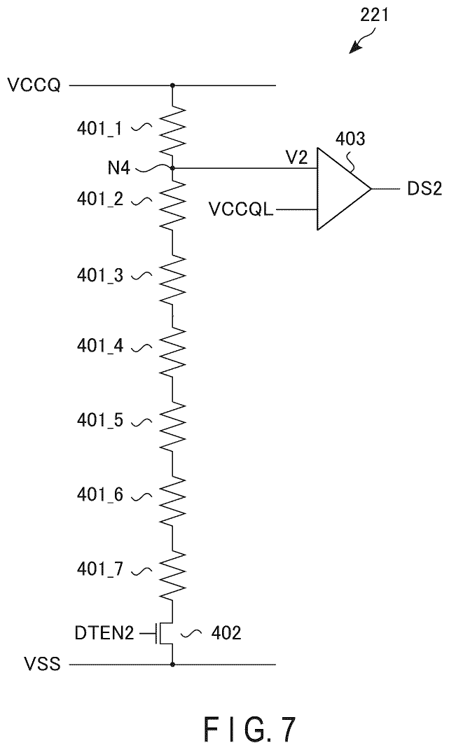

An example of a configuration of the detection circuit will be described below with reference to FIGS. 6 and 7. FIG. 6 is a circuit diagram of the detection circuit 101. FIG. 7 is a circuit diagram of the detection circuit 221.

First, the detection circuit 101 of the memory controller 10 will be described.

As shown in FIG. 6, the detection circuit 101 includes a plurality of resistance elements 301, an n-channel metal oxide semiconductor field effect transistor (MOSFET) 302, and a comparison circuit 303. Hereinafter, the n-channel MOSFET will also be referred to as “NMOS transistor.”

The resistance elements 301 are used to divide the voltage VCCQ. In the example of FIG. 6, the detection circuit 101 includes, for example, seven resistance elements 301_1 to 301_7. Note that the resistive elements 301_1 to 301_7 may have the same resistance value or different resistance values. The number of resistance elements 301 is not limited to seven. The detection circuit 101 may include at least two or more resistance elements 301 to divide the voltage VCCQ. The resistance elements 301_1 to 301_7 are coupled in series. The voltage VCCQ is applied to one end of the resistance element 301_1. One end of the resistance element 301_7 is coupled to the NMOS transistor 302. For example, a voltage V1 at a node N3 where the resistance elements 301_1 and 301_2 are coupled is applied to the comparison circuit 303. The voltage V1 is a determination voltage for use in the comparison circuit 303.

The NMOS transistor 302 is a switching element. The NMOS transistor 302 controls ON/OFF of current flowing through the resistance elements 301_1 to 301_7. For example, a drain of the NMOS transistor 302 is coupled to one end of the resistance element 301_7. A ground voltage VSS is applied to a source of the NMOS transistor 302. In other words, the source of the NMOS transistor 302 is grounded. A gate of the NMOS transistor 302 is supplied with a signal DTEN1. If the signal DTEN1 is, for example, at the “H” level, the NMOS transistor 302 is turned on. That is, the detection circuit 101 is enabled. On the other hand, if the signal DTEN1 is, for example, at the “L” level, the NMOS transistor 302 is turned off.

If the resistance value of the resistance element 301 is R_{R1} and the on-resistance of the NMOS transistor 302 is Rₒₙ, the voltage V1 of the enabled node N3 can be expressed as V1=VCCQ×(6R_{R1}+Rₒₙ)/(7R_{R1}+Rₒₙ). The resistance value R_{R1} of the resistance element 301 is appropriately set so that the voltage V1 is lower than or equal to VCCQ and higher than the voltage VCCQ/2.

The comparison circuit 303 is a circuit that compares the voltage VCCQL and the voltage V1. The voltage V1 is applied to one input terminal of the comparison circuit 303. The voltage VCCQL is applied to the other input terminal of the comparison circuit 303. The comparison circuit 303 outputs a signal DS1 based on a result of the comparison. The comparison circuit 303 sets the signal DS1 at the “L” level if the voltage VCCQL is, for example, higher than or equal to the voltage V1. On the other hand, the comparison circuit 303 sets the signal DS1 the “H” level if the voltage VCCQL is, for example, lower than the voltage V1.

Next is a description of the detection circuit 221 of the semiconductor memory device 20. In the example of FIG. 7, the detection circuit 101 and the detection circuit 221 have the same configuration, but may have different configurations.

As shown in FIG. 7, the detection circuit 221 includes a plurality of resistance elements 401, an NMOS transistor 402 and a comparison circuit 403.

The resistance elements 401 are used to divide the voltage VCCQ. The resistance elements 401_1 to 401_7 correspond to the resistance elements 301_1 to 301_7 of FIG. 6. The resistance elements 401_1 to 401_7 are coupled in series. A voltage VCCQ is applied to one end of the resistance element 401_1. One end of the resistance element 401_7 is coupled to the NMOS transistor 402. A voltage V2 at a node N4 where the resistance elements 401_1 and 401_2 are coupled is applied to the comparison circuit 403. The voltage V2 is a determination voltage for use in the comparison circuit 403.

The NMOS transistor 402 is a switching element. The NMOS transistor 402 corresponds to the NMOS transistor 302 of FIG. 6. For example, a drain of the NMOS transistor 402 is coupled to one end of the resistance element 401_7. For example, the voltage VSS is applied to a source of the NMOS transistor 402. In other words, the source of the NMOS transistor 402 is grounded. A gate of the NMOS transistor 402 is supplied with a signal DTEN2. The NMOS transistor 402 is turned on if the signal DTEN2 is, for example, at the “H” level. That is, the detection circuit 221 is enabled. On the other hand, the NMOS transistor 402 is turned off if the signal DTEN2 is, for example, at the “L” level.

Like in the detection circuit 101, if, for example, the resistance value of the resistance element 401 is R_{R2} and the on-resistance of the NMOS transistor 402 is Rₒₙ, the voltage V2 of the enabled node N4 can be expressed as V2=VCCQ×(6R_{R2}+Rₒₙ)/(7R_{R2}+Rₒₙ). The resistance value R_{R2} of the resistance element 401 is appropriately set so that the voltage V2 is lower than or equal to VCCQ and higher than the voltage VCCQ/2.

The comparison circuit 403 compares the voltage VCCQL and the voltage V2. The comparison circuit 403 corresponds to the comparison circuit 303 of FIG. 6. The voltage V2 is applied to one input terminal of the comparison circuit 403. The voltage VCCQL is applied to the other input terminal of the comparison circuit 403. The comparison circuit 403 outputs a signal DS2 based on a result of the comparison. The comparison circuit 403 sets the signal DS2 at the “L” level if the voltage VCCQL is, for example, equal to or higher than the voltage V2. On the other hand, the comparison circuit 403 sets the signal DS2 at the “H” level if the voltage VCCQL is, for example, lower than the voltage V2.

### 1.1.8 Configurations of Receiving Unit and Termination Circuit

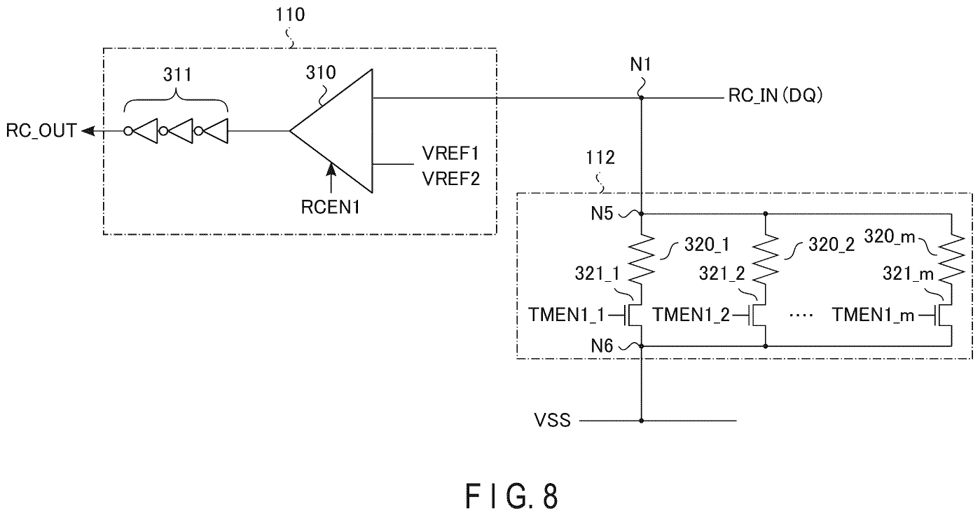

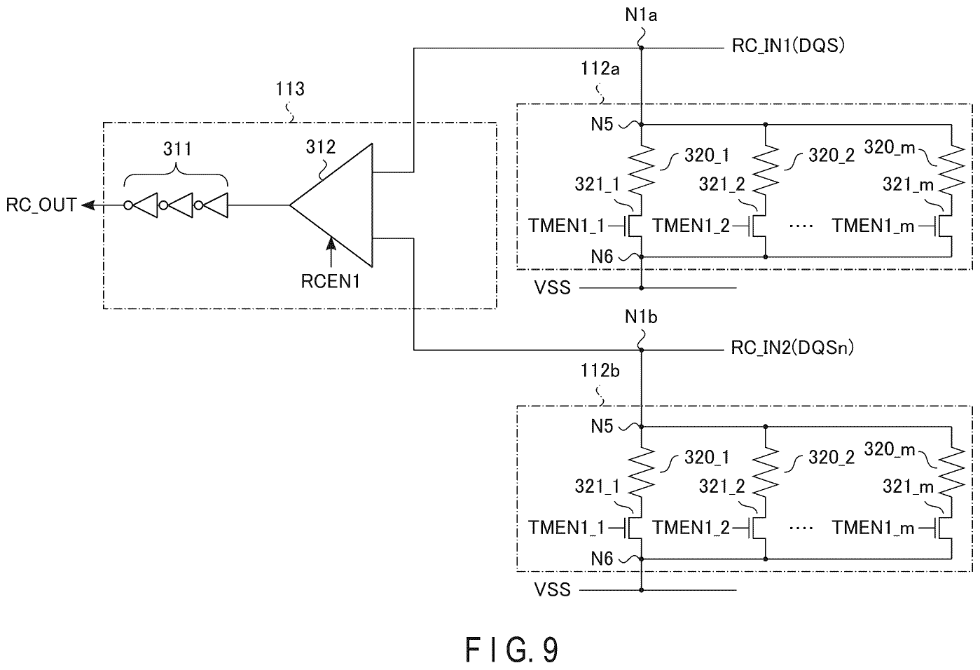

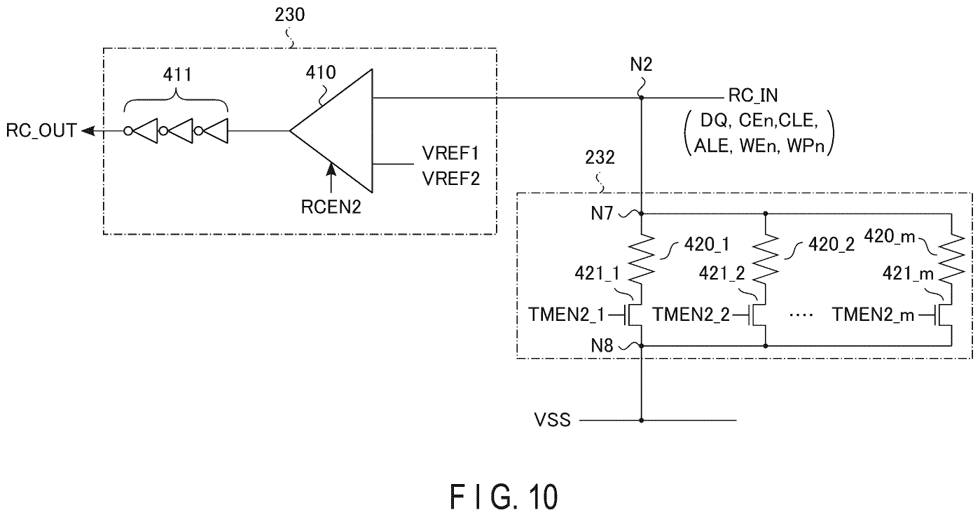

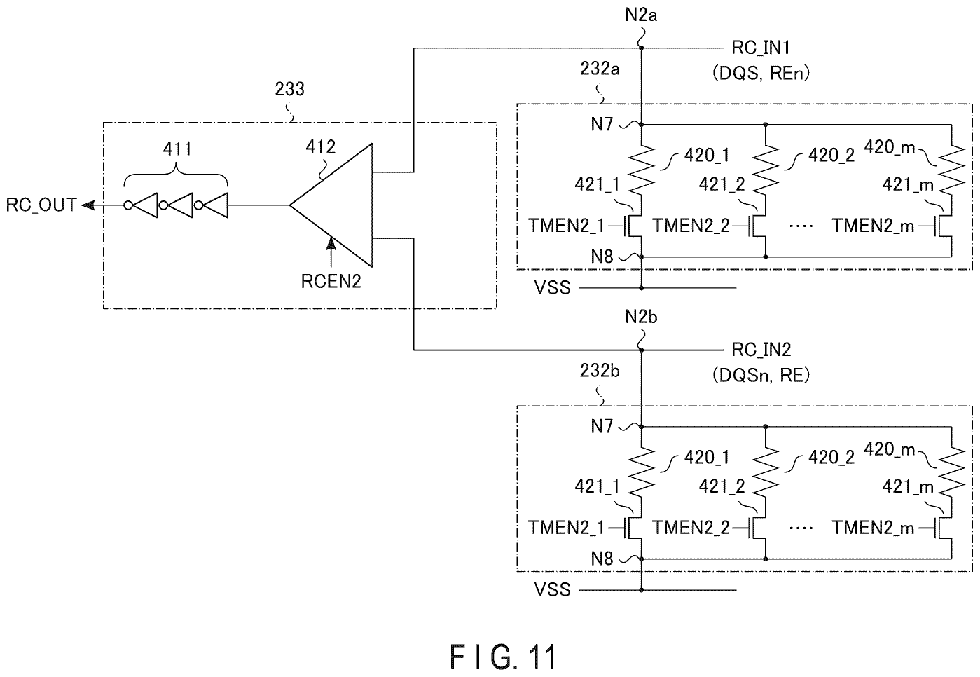

An example of a configuration of each of the receiving unit and the termination circuit will be described below with reference to FIGS. 8 to 11. FIG. 8 is a circuit diagram of the receiving unit 110 and the termination circuit 112 in the transmit/receive circuit 104. FIG. 9 is a circuit diagram of the receiving unit 113 and the termination circuits 112a and 112b in the transmit/receive circuit 105. FIG. 10 is a circuit diagram of the receiving unit 230 and the termination circuit 232 in the transmit/receive circuit 224. FIG. 11 is a circuit diagram of the receiving unit 233 and the termination circuits 232a and 232b in the transmit/receive circuit 225.

First is a description of the receiving unit 110 and the termination circuit 112 of the transmit/receive circuit 104. FIG. 8 shows an example of the receiving unit 110 and the termination circuit 112 of one of the transmit/receive circuits 104. In the example of FIG. 8, the transmitting unit 111 of the transmit/receive circuit 104 is omitted

As shown in FIG. 8, the receiving unit 110 includes a comparison circuit 310 and a plurality of inverters 311.

The comparison circuit 310 is a circuit that compares the voltage of the input signal RC_IN and the reference voltage VREF1 or VREF2. The signal DQ is input as the input signal RC_IN of the transmit/receive circuit 104. Upon receiving, for example, the “H” level signal RCEN1, the comparison circuit 310 is enabled. In the example of FIG. 8, the signal DQ is applied to one input terminal of the comparison circuit 310 via the node N1. The voltage VREF1 or VREF2 is applied to the other input terminal of the comparison circuit 310. The comparison circuit 310 determines the logical level of the input signal RC_IN based on a comparison result. For example, in the LTT mode, if the voltage of the input signal RC_IN is equal to or higher than the reference voltage VREF1, the output signal RC_OUT is set at the “H” level. For example, in the PI LTT mode, if the voltage of the input signal RC_IN is equal to or higher than the reference voltage VREF2, the output signal RC_OUT is set at the “H” level. The comparison circuit 310 converts the output signal RC_OUT into an appropriate voltage level for processing in the memory controller 10, and outputs it. For example, the comparison circuit 310 outputs a signal of the voltage VCCQ at the “H” level and outputs a signal of the voltage VSS at the “L” level.

The inverters 311 are circuits that output an inverted signal of an input signal. The signal input from the input terminal of each of the inverters 311 is inversely output. In the example of FIG. 8, three inverters 311 are coupled in series, but the number of inverters 311 can be discretionarily determined. Note that the inverters 311 may be excluded.

Performing a termination process, the termination circuit 112 applies the voltage VSS to a signal line via a termination resistor. In other words, the signal line is grounded via the termination resistor. The termination circuit 112 sets a resistance value of the termination resistor to a different value for each interface mode.

The termination circuit 112 includes, for example, a plurality of resistance elements 320 and a plurality of NMOS transistors 321. The NMOS transistors 321 function as switching elements. The resistance elements 320 and NMOS transistors 321 constitute a variable resistance circuit of terminal resistor. Note that the configuration of the termination circuit 112 is not limited to that shown in FIG. 8.

In the example of FIG. 8, the termination circuit 112 includes m resistance elements 320_1 to 320_m and m NMOS transistors 321_1 to 321_m (m is an integer larger than or equal to 2). There are m sets of one resistance element 320 and one NMOS transistor 321 which are coupled in series. The m sets are coupled in parallel. More specifically, for example, the resistance element 320_1 and the NMOS transistor 321_1 constitute one set. One end of the resistance element 320_1 is coupled to a node N5. The node N5 is coupled to the node N1. The other end of the resistance element 320_1 is coupled to a drain of the NMOS transistor 321_1. A gate of the NMOS transistor 321_1 is supplied with a signal TMEN1_1. The signal TMEN1_1 is a signal that controls the ON/OFF of the NMOS transistor 321_1. The signal TMEN1_1 is received from the enable signal generator 102. A source of the NMOS transistor 321_1 is coupled to a node N6. The voltage VSS is applied to the node N6. In other words, the source of the NMOS transistor 321_1 is grounded.

Similarly, for example, the resistance element 320_2 and the NMOS transistor 321_2 constitute one set. A gate of the NMOS transistor 321_2 is supplied with a signal TMEN1_2. For example, the resistance element 320_m and the NMOS transistor 321_m constitute one set. A gate of the NMOS transistor 321_m is supplied with a signal TMEN1_m.

The signals TMEN1_1 to TMEN1_m are controlled based on the interface mode. For example, if the termination circuit 112 is disabled (if no termination process is performed), the enable signal generator 102 sets the signals TMEN1_1 to TMEN1_m at the “L” level. That is, the NMOS transistors 321_1 to 321_m are turned off. For example, the enable signal generator 102 controls the signals TMEN1_1 to TMEN1_m so that the resistance value of combined resistance (that is, terminal resistance) of the resistance elements 320 and the NMOS transistors 321 is higher in the PI LTT mode than in the LTT mode.

In the example of FIG. 8, the variable resistance circuit of the termination resistor is configured by a plurality of resistance elements 320 and a plurality of NMOS transistors 321, but the termination circuit 112 is not limited to this configuration. For example, the resistance value of the termination resistor may be a fixed value regardless of the LTT mode or the PI LTT mode. In this case, for example, the termination circuit 112 includes one resistance element 320 and one NMOS transistor 321. In addition, the termination resistor may be excluded from the termination circuit 112. In this case, for example, the termination circuit 112 includes one NMOS transistor 321.

Next is a description of the receiving unit 113 and termination circuits 112a and 112b of the transmit/receive circuit 105. In the example of FIG. 9, the transmitting units 111a and 111b of the transmit/receive circuit 105 are omitted.

As shown in FIG. 9, the receiving unit 113 includes a differential circuit 312 and a plurality of inverters 311.

The differential circuit 312 is a circuit that outputs a signal based on a difference in voltage between the input signal RC_IN1 and the input signal RC_IN2. For example, the signal DOS is input as the input signal RC_IN1. The signal DOSn is input as the input signal RC_IN2. Upon receiving, for example, the “H” level signal RCEN1, the differential circuit 312 is enabled. In the example of FIG. 9, the signal DQS is applied to one input terminal of the differential circuit 312 via a node N1a. The signal DOSn is applied to the other input terminal of the differential circuit 312 via a node N1b. The differential circuit 312 determines the logical level of the output signal RC_OUT based on a difference in voltage between the signal DOS and the signal DQSn. The differential circuit 312 converts the output signal RC_OUT into an appropriate voltage level for processing in the memory controller 10 and outputs it. For example, the differential circuit 312 outputs a signal of the voltage VCCQ at the “H” level and outputs a signal of the voltage VSS at the “L” level.

The configuration of the inverter 311 is similar to that of the inverter 311 shown in FIG. 8.

The configuration of the termination circuits 112a and 112b is similar to that of the termination circuit 112 shown in FIG. 8. The termination circuit 112a is coupled to the node N1a. The termination circuit 112b is coupled to the node N1b.

Next is a description of the receiving unit 230 and termination circuit 232 of the transmit/receive circuit 224. Note that the configurations of the receiving units 230 and termination circuits 232 in the transmit/receive circuit 224 and the receiving circuit 227 are the same. FIG. 10 shows an example of a receiving unit 230 and a termination circuit 232 of the transmit/receive circuit 224 corresponding to the signal DQ. Note that the transmitting unit 231 of the transmit/receive circuit 224 is omitted from the example of FIG. 10. In the example of FIG. 10, the receiving unit 230 and termination circuit 232 have the same configuration as that of the receiving unit 110 and termination circuit 112 shown in FIG. 8, but the configurations may be different from each other.

As shown in FIG. 10, the receiving unit 230 includes a comparison circuit 410 and a plurality of inverters 411.

The comparison circuit 410 is a circuit that compares the voltage of an input signal RC_IN and the reference voltage VREF1 or VREF2. For example, the transmit/receive circuit 224 is supplied with a signal DQ as the input signal RC_IN. For example, the receiving circuit 227 is supplied with one of signals CEn, CLE, ALE, WEn, and WPn as the input signal RC_IN. Upon receiving, for example, the “H” level signal RCEN2, the comparison circuit 410 is enabled. The comparison circuit 410 corresponds to the comparison circuit 310 of FIG. 8. The signal DO is applied to one input terminal of the comparison circuit 410 via the node N2. The voltage VREF1 or VREF2 is applied to the other input terminal of the comparison circuit 410.

The inverters 411 are circuits that output an inverted signal of an input signal. The inverters 411 correspond to the inverters 311 of FIG. 8.

Performing a termination process, the termination circuit 232 applies the voltage VSS to a signal line via a termination resistor. In other words, the signal line is grounded via the termination resistor. The termination circuit 232 sets the resistance value of the termination resistor to a different value for each interface mode.

The termination circuit 232 includes, for example, a plurality of resistance elements 420 and a plurality of NMOS transistors 421. The NMOS transistors 421 function as switching elements. In the example of FIG. 10, termination circuit 232 includes m resistance elements 420_1 to 420_m and m NMOS transistors 421_1 to 421_m. The resistance elements 420_1 to 420_m and NMOS transistor 421_1 to 421_m respectively correspond to the resistance elements 320_1 to 320_m and NMOS transistors 321_1 to 321_m in FIG. 8. A set of m resistance elements 420 and a set of m NMOS transistors 421 are coupled in parallel between a node N7 and a node N8. The node N7 is coupled to the node N2. The voltage VSS is applied to the node N8. Signals TMEN2_1 to TMEN2_m are input to gates of the NMOS transistors 421_1 to 421_m, respectively.

The signals TMEN2_1 to TMEN2_m are controlled based on the interface mode. If the termination circuit 232 is, for example, disabled (if no termination process is performed), the enable signal generator 102 sets the signals TMEN2_1 to TMEN1_m at the “L” level. That is, the NMOS transistors 421_1 to 421_m is turned off. For example, the enable signal generator 222 controls the signals TMEN2_1 to TMEN2_m so that the resistance value of combined resistance (that is, terminal resistance) of the resistance elements 420 and the NMOS transistors 421 is higher in the PI LTT mode than in the LTT mode.

Next is a description of the receiving unit 233 and termination circuits 232a and 232b of the transmit/receive circuit 225. In the example of FIG. 11, the transmitting units 231a and 231b of the transmit/receive circuit 225 are omitted. The configuration of the receiving unit 233 and termination circuits 232a and 232b in the example of FIG. 11 is the same as that of the receiving unit 113 and termination circuits 112a and 112b in FIG. 9, but may be different from each other.

As shown in FIG. 11, the receiving unit 233 includes a differential circuit 412 and a plurality of inverters 411.

The differential circuit 412 is a circuit that outputs a signal based on a difference in voltage between an input signal RC_IN1 and an input signal RC_IN2. For example, the transmit/receive circuit 225 is supplied with the signal DOS as the input signal RC_IN1 and the signal DOSn as the input signal RC_IN2. For example, the receiving circuit 226 is supplied with, for example, the signal REn as the input signal RC_IN1 and the signal RE as the input signal RC_IN2. Upon receiving, for example, the “H” level signal RCEN1, the differential circuit 412 is enabled. The differential circuit 412 corresponds to the differential circuit 312 of FIG. 9. The signal DOS is applied to one input terminal of the differential circuit 412 via the node N2a. The signal DOSn is supplied to the other input terminal of the differential circuit 412 via the node N2b. The differential circuit 412 determines the logical level of the output signal RC_OUT based on the difference in voltage between the signals DOS and DQSn.

The configuration of the inverters 411 is similar to that of the inverters 411 of FIG. 10.

The termination circuits 232a and 232b are similar to the termination circuit 232 of FIG. 10. The termination circuit 232a is coupled to the node N2a. The termination circuit 232b is coupled to the node N1b.

### 1.1.9 Configuration of Transmitting Unit

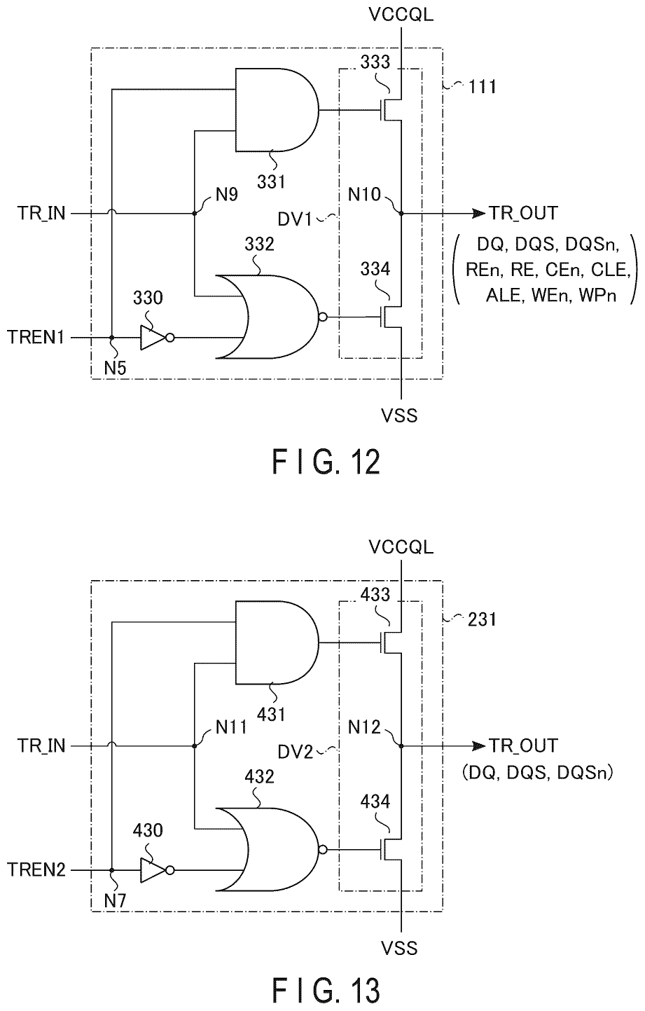

An example of a configuration of the transmitting unit will be described below with reference to FIGS. 12 and 13. FIG. 12 is a circuit diagram of the transmitting unit 111. FIG. 13 is a circuit diagram of the transmitting unit 231.

First, the transmitting unit 111 of the transmit/receive circuit 104 will be described. The configurations of the transmitting unit 111 of the transmit/receive circuit 104, the transmitting units 111a and 111b of the transmit/receive circuit 105, the transmitting units 111a and 111b of the transmitting circuit 106, and the transmitting unit 111 of the transmitting circuit 107 are the same.

As shown in FIG. 12, the transmitting unit 111 includes an inverter 330, an AND circuit 331, a NOR circuit 332, and two NMOS transistors 333 and 334. The two NMOS transistors 333 and 334 function as a driver DV1 that outputs the signal TR_OUT. For example, the transmitting unit 111 of the transmit/receive circuit 104 outputs the signal DQ as the output signal TR_OUT. For example, the transmitting unit 111a of the transmit/receive circuit 105 outputs the signal DQS as the output signal TR_OUT. For example, the transmitting unit 111b of the transmit/receive circuit 105 outputs the signal DOSn as the output signal TR_OUT. For example, the transmitting unit 111a of the transmitting circuit 106 outputs the signal REn as the output signal TR_OUT. For example, the transmitting unit 111b of the transmitting circuit 106 outputs the signal RE as the output signal TR_OUT. For example, the transmitting circuit 107 outputs one of signals CEn, CLE, ALE, WEn, and WPn as the output signal TR_OUT.

The inverter 330 inverts the signal TREN1. The inverter 330 transmits the inverted signal TREN1 to the NOR circuit 332.

The AND circuit 331 is an AND arithmetic circuit. The signal TREN1 is input to one input terminal of the AND circuit 331. The input signal TR_IN, that is, a signal to be transmitted to the semiconductor memory device 20, is input to the other input terminal of the AND circuit 331 via a node N9. The AND circuit 331 outputs the “H” level signal if at least one of the signal TREN1 and input signal TR_IN is at the “H” level.

The NOR circuit 332 is a NOR arithmetic circuit. The input signal TR_IN is input to one input terminal of the NOR circuit 332 via the node N9. The inverted signal of the signal TREN1 output from the inverter 330 is input to the other input terminal of the NOR circuit 332. If the input signal TR_IN and the inverted signal of the signal TREN1 are both at the “L” level, the NOR circuit 332 outputs the “H” level signal.

The voltage VCCQL is applied to a drain of the NMOS transistor 333. A source of the NMOS transistor 333 is coupled to the output terminal of the transmitting unit 111 via a node N10. The output signal of the AND circuit 331 is input to a gate of the NMOS transistor 333.

A drain of the NMOS transistor 334 is coupled to the output terminal of the transmitting unit 111 via the node N10. Note that a resistance element may be provided between the node N10 and the NMOS transistor 334. The voltage VSS is applied to a source of the NMOS transistor 334. The output signal of the NOR circuit 332 is input to a gate of the NMOS transistor 334.

If the signal TREN1 and the input signal TR_IN are, for example, at the “H” level, the NMOS transistor 333 is turned on. As a result, the transmitting unit 111 outputs the output signal TR_OUT at the “H” level. If the signal TREN1 is at the “H” level and the input signal TR_IN is at the “L” level, the NMOS transistor 334 is turned on. As a result, the transmitting unit 111 outputs the output signal TR_OUT at the “L level. If, for example, the voltage VCCQL is equal to VCCQ, the output signal TR_OUT corresponding to the LTT mode is output. If the voltage VCCQL is equal to VCCQ/2, the output signal TR_OUT corresponding to the PI LTT mode is output.

Next is a description of the transmitting unit 231. In the example of FIG. 13, the transmitting unit 231 has the same configuration as that of the transmitting unit 111 of FIG. 12, but they may have different configurations each other. In addition, the configurations of the transmitting unit 231 of the transmit/receive circuit 224 and the transmitting units 231a and 231b of the transmit/receive circuit 225 are the same.

As shown in FIG. 13, the transmitting unit 231 includes an inverter 430, an AND circuit 431, a NOR circuit 432, and two NMOS transistors 433 and 434. The two NMOS transistors 433 and 434 function as a driver DV2 that outputs the signal TR_OUT. For example, the transmitting unit 231 of the transmit/receive circuit 224 outputs the signal DQ as the output signal TR_OUT. For example, the transmitting unit 231a of the transmit/receive circuit 225 outputs the signal DQS as the output signal TR_OUT. For example, the transmitting unit 231b of the transmit/receive circuit 225 outputs the signal DOSn as the output signal TR_OUT.

The inverter 430 inverts the signal TREN2. The inverter 430 transmits the inverted signal TREN2 to the NOR circuit 432.

The AND circuit 431 is an AND arithmetic circuit. The signal TREN2 is input to one input terminal of the AND circuit 431. The input signal TR_IN, that is, a signal to be transmitted to the memory controller 10, is input to the other input terminal of the AND circuit 431 via a node N11. The AND circuit 431 outputs the “H” level signal if at least one of the signal TREN2 and input signal TR_IN is at the “H” level.

The NOR circuit 432 is a NOR arithmetic circuit. The input signal TR_IN is input to one input terminal of the NOR circuit 432 via the node N11. The inverted signal of the signal TREN2 output from the inverter 430 is input to the other input terminal of the NOR circuit 432. If the input signal TR_IN and the inverted signal of the signal TREN2 are both at the “L” level, the NOR circuit 432 outputs the “H” level signal. The voltage VCCQL is applied to a drain of the NMOS transistor 433. A source of the NMOS transistor 433 is coupled to the output terminal of the transmitting unit 231 via a node N12. The output signal of the AND circuit 431 is input to a gate of the NMOS transistor 433.

A drain of the NMOS transistor 434 is coupled to the output terminal of the transmitting unit 231 via the node N12. Note that a resistance element may be provided between the node N12 and the NMOS transistor 434. The voltage VSS is applied to a source of the NMOS transistor 434. The output signal of the NOR circuit 432 is input to a gate of the NMOS transistor 434.

If the signal TREN2 and the input signal TR_IN are, for example, at the “H” level, the NMOS transistor 433 is turned on. As a result, the transmitting unit 231 outputs the “H” level output signal TR_OUT. If the signal TREN1 is at the “H” level and the input signal TR_IN is at the “L” level, the NMOS transistor 434 is turned on. As a result, the transmitting unit 231 outputs the “L” level output signal TR_OUT. If, for example, the voltage VCCQL is equal to VCCQ, the output signal TR_OUT corresponding to the LTT mode is output. If the voltage VCCQL is equal to VCCQ/2, the output signal TR_OUT corresponding to the PI LTT mode is output.

### 1.2 Specific Examples of Amplitude Waveforms of Signals

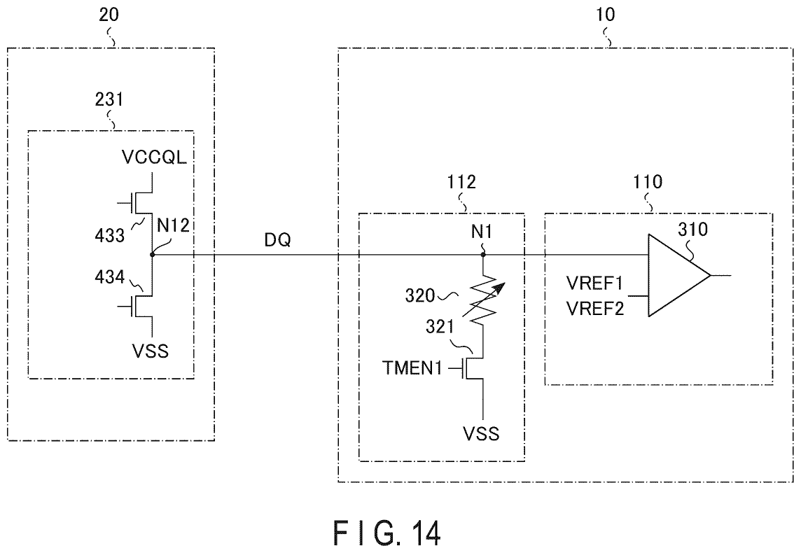

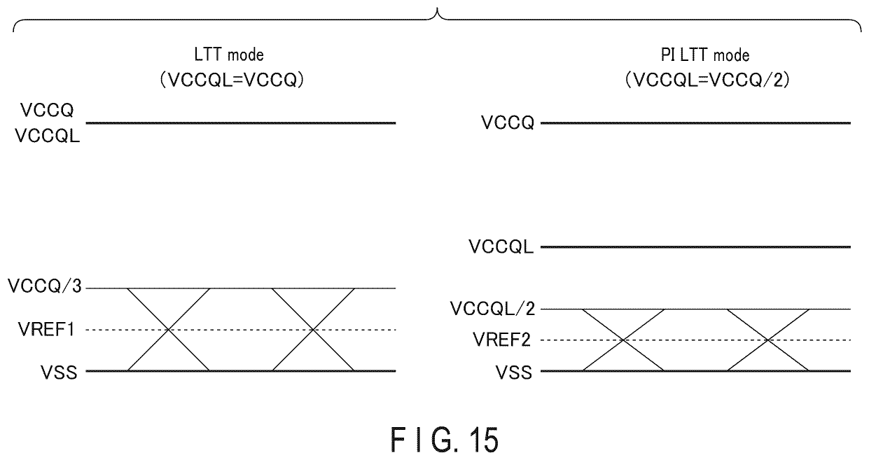

A specific example of amplitude waveforms of signals in the LTT and PI LTT modes will be described below with reference to FIGS. 14 and 15. FIG. 14 is a conceptual diagram of a case in which the signal DQ is transmitted from the transmitting unit 231 of the semiconductor memory device 20 to the receiving unit 110 of the memory controller 10. In the example of FIG. 14, part of the configuration of the receiving unit 110 is extracted and so is part of the configuration of the transmitting unit 231. FIG. 15 is a diagram showing an example of signal waveforms of signals input to the receiving unit 110 in the LTT mode and the PI LTT mode.

As shown in FIG. 14, the termination circuit 112 is enabled when the semiconductor memory device 20 transmits the signal DO to the memory controller 10. That is, the NMOS transistor 321 is turned on. Accordingly, a signal line that transmits the signal DQ is terminated. More specifically, the signal line is grounded (voltage VSS is applied) via the resistance element 320 at the node N1. For example, in the LTT mode, a voltage VCCQL that is equal to VCCQ is applied to the NMOS transistor 433 of the transmitting unit 231. In the PI LTT mode, a voltage VCCQL that is equal to VCCQ/2 is applied to the NMOS transistor 433 of the transmitting unit 231. Thus, the amplitude of the signal DQ is smaller in the PI LTT mode than in the LTT mode. In addition, the upper limit value of the amplitude of the signal DQ (the voltage value at the “H” level) is lower in the PI LTT mode than in the LTT mode. The lower limit values of the amplitudes of the signals DQ (the voltage values of at the “L” level) are the same in the LTT and PI LTT modes.

More specifically, as shown in FIG. 15, in the LTT mode, that is, when the voltage VCCQL is equal to the voltage VCCQ, the upper limit value of the voltage value of the signal DQ in the receiving unit 110 (the voltage value at the “H” level) decreases, for example, from the voltage VCCQ to a voltage VCCQ/3. In this case, the amplitude of the signal is from the voltage VSS to the voltage VCCQ/3. In this case, the reference voltage VREF1 is set to a voltage value that is higher than the voltage VSS and lower than the voltage VCCQ/3. The voltage VREF1 is preferably set to a voltage VCCQ/6 that is intermediate between the voltage VSS and the voltage VCCQ/3.

In the PI LTT mode, that is, when the voltage VCCQL is equal to the voltage VCCQ/2, the upper limit value of the voltage value of the signal DQ in the receiving unit 110 decreases, for example, from the VCCQ/2 to the voltage VCCQL/2 (=VCCQ/4). In this case, the amplitude of the signal is from the voltage VSS to the voltage VCCQ/4. Therefore, the upper limit value and amplitude of the voltage value of the signal in the PI LTT mode are lower than those in the LTT mode. The lower limit of the voltage value of the signal in the PI LTT mode is the same as that in the LTT mode. In the PI LTT mode, the reference voltage VREF2 is set to a voltage value that is higher than the voltage VSS and lower than the voltage VCCQL/2 (=VCCQ/4). The voltage VREF2 is preferably set to the voltage VCCQL/4 (=VCCQ/8) which is intermediate between the voltage VSS and the voltage VCCQL/2. Therefore, the voltage VREF2 is set to a voltage value that is lower than the voltage VREF1.

### 1.3 Advantages of Embodiment

For example, in the next-generation product of NAND type flash memories to which LTT is applied as an interface standard, PI LTT can be adopted as the interface standard. In this case, a next-generation product that supports both LTT and PI LTT may be required from the viewpoint of backward compatibility.

In contrast to the above, in the configuration according to the present embodiment, the semiconductor memory device 20 includes a voltage VCCQL detection circuit, and a reference voltage generator, a transmitting circuit, a receiving circuit, and a termination circuit which are adaptable to LTT and PI LTT modes. The semiconductor memory device 20 can thus select one of the LTT and PI LTT modes.

In the configuration according to the present embodiment, one of the LTT and PI LTT modes is selected based on the voltage value of the voltage VCCQL. Therefore, when the semiconductor memory device 20 is started, the initial setting of the interface mode can be omitted to suppress the startup time of the semiconductor memory device 20 from increasing.

### 2. Second Embodiment

A second embodiment will be described below. The configuration of a memory system 3 of the second embodiment, which differs from that of the memory system 3 of the first embodiment, will be described.

Hereinafter, the description will focus on the difference from the first embodiment.

### 2.1 Configuration of Memory System

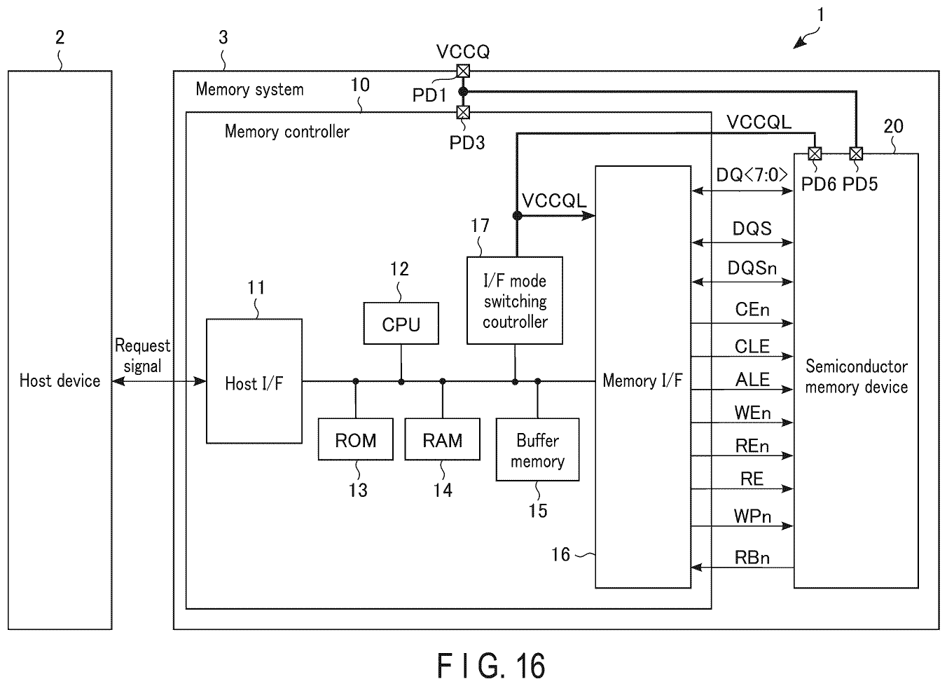

An example of a configuration of the memory system 3 will be described with reference to FIG. 16. FIG. 16 is a block diagram showing the overall configuration of a data processing device 1. In the example of FIG. 16, some of the couplings between components are indicated by arrows, but the couplings between components are not limited to the arrows.

As shown in FIG. 16, the memory system 3 includes an electrode pad PD1. The memory system 3 is supplied with the voltage VCCQ from an external device (e.g., a host device 2) via the electrode pad PD1. In the memory system 3 of the second embodiment, the electrode pad PD2 of the first embodiment is excluded. That is, the voltage VCCQL is not supplied to the memory system 3 from the external device.

The memory controller 10 includes an electrode pad PD3. The memory controller 10 is supplied with the voltage VCCQ via an electrode pad PD3. In the memory controller 10 of the second embodiment, the electrode pad PD4 of the first embodiment is excluded.

The memory controller 10 includes a host interface circuit 11, a CPU 12, a ROM 13, a RAM 14, a buffer memory 15, a memory interface circuit 16, and an interface (I/F) mode selecting controller 17.

The interface mode switching controller 17 is a circuit that controls an interface mode between the memory controller 10 and the semiconductor memory device 20. The interface mode switching controller 17 generates the voltage VCCQL under the control of the CPU 12. The interface mode switching controller 17 generates the voltage VCCQL whose voltage value varies from mode to mode. The voltage VCCQL in the PI LTT mode is set lower than the voltage VCCQL in the LTT mode. More specifically, the interface mode switching controller 17 sets the voltage VCCQL equal to VCCQ in the LTT mode, for example. In addition, the interface mode switching controller 17 sets the voltage VCCQL equal to voltage VCCQ/2 in the PI LTT mode, for example. The interface mode switching controller 17 supplies the voltage VCCQL to the memory interface circuit 16 and the electrode pad PD6 of the semiconductor memory device 20.

### 2.2 Advantages of Second Embodiment

The configuration according to the second embodiment brings about the same advantages as those of the first embodiment.

With the configuration according to the second embodiment, the memory controller 10 can select an interface mode between the memory controller 10 and the semiconductor memory device 20. Therefore, for example, the interface mode can be changed under the control of the memory controller 10.

### 3. Modification, Etc

According to the above embodiment, a semiconductor memory device includes a nonvolatile memory cell (MC), a detection circuit (221) which detects a first voltage (VCCQL) and selects one of a first mode (LTT mode) and a second mode (PI LTT mode) based on the first voltage, and a transmitting unit (231) which outputs a first signal corresponding to the one of the first mode and the second mode. The detection circuit selects the first mode when the first voltage is equal to or greater than a determination value (V2), and selects the second mode when the first voltage is less than the determination value. The transmitting unit outputs the first signal of a first amplitude in the first mode, and outputs the first signal of a second amplitude that is smaller than the first amplitude in the second mode.

A semiconductor memory device and a memory system capable of switching a communication system between a memory controller and a semiconductor memory device can be provided.

It should be noted that the embodiments are not limited to the above descriptions but various modifications can be made.

For example, in the above embodiments, the memory controller 10 may include a transmit/receive circuit 104 as a transmit/receive circuit that transmits and receives signals DQS and DQSn. In this case, the memory controller 10 includes a transmit/receive circuit 104 adapted to the signal DOS and a transmit/receive circuit 104 adapted to the signal DQSn. Similarly, the semiconductor memory device 20 may include a transmit/receive circuit 224 as a transmit/receive circuit that transmits and receives signals DOS and DQSn. In this case, the semiconductor memory device 20 includes a transmit/receive circuit 224 adapted to the signal DQS and a transmit/receive circuit 224 adapted to the signal DQSn.

Furthermore, in the foregoing embodiments, the memory controller 10 may include a transmitting circuit 107 as a transmitting circuit that transmits signals REn and RE. In this case, the memory controller 10 includes a transmitting circuit 107 adapted to the signal REn and a transmitting circuit 107 adapted to the signal RE. Similarly, the semiconductor memory device 20 may include a receiving circuit 227 as a receiving circuit that receives signals REn and RE. In this case, the semiconductor memory device 20 includes a receiving circuit 227 adapted to the signal REn and a receiving circuit 227 adapted to the signal RE.

In addition, the term “coupled” or “coupling” in the foregoing embodiments also includes an indirect coupling of two things between which a transistor, a resistor or the like is interposed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a nonvolatile memory cell;
a detection circuit which detects a first voltage and selects one of a first mode and a second mode based on the first voltage; and
a transmitting unit which outputs a first signal corresponding to the one of the first mode and the second mode, wherein
the detection circuit selects the first mode when the first voltage is equal to or greater than a determination value, and selects the second mode when the first voltage is less than the determination value, and
the transmitting unit outputs the first signal of a first amplitude in the first mode, and outputs the first signal of a second amplitude that is smaller than the first amplitude in the second mode.

2. The semiconductor memory device according to claim 1, further comprising:
a receiving unit which receives a second signal corresponding to the one of the first mode and the second mode; and
a termination circuit coupled to the receiving unit.

3. The semiconductor memory device according to claim 2, further comprising a reference voltage generator which generates one of a first reference voltage corresponding to the first mode and a second reference voltage corresponding to the second mode,
wherein the receiving unit compares the second signal and the first reference voltage in the first mode, and compares the second signal and the second reference voltage in the second mode, to determine a logical level of the second signal.

4. The semiconductor memory device according to claim 3, wherein the second reference voltage is lower than the first reference voltage.

5. The semiconductor memory device according to claim 2, wherein the termination circuit is grounded with a first resistance value in the first mode and is grounded with a second resistance value that is larger than the first resistance value in the second mode.

6. The semiconductor memory device according to claim 1, wherein the first amplitude has an upper limit that is higher than an upper limit of the second amplitude.

7. The semiconductor memory device according to claim 1, wherein the first amplitude has a lower limit that is equal to a lower limit of the second amplitude.

8. The semiconductor memory device according to claim 1, wherein:
the transmitting unit includes an output drive including a first NMOS transistor and a second NMOS transistor which is coupled in series to the first NMOS transistor; and
The first voltage is applied to a drain of the first NMOS transistor, a source of the first NMOS transistor is coupled to a drain of the second NMOS transistor, and the second voltage is applied to a source of the second NMOS transistor.

9. The semiconductor memory device according to claim 1, wherein the semiconductor memory device is a NAND flash memory.

10. A memory system comprising:
the semiconductor memory device according to claim 1; and
a memory controller which controls the semiconductor memory device and generates the first voltage.
